(19) United States
(12) Patent Application Publication
(10) Pub. No.: US 2025/0126944 A1
(43) Pub. Date: Apr. 17, 2025

(54) DISPLAY DEVICE AND REPAIRING METHOD THEREOF

(71) Applicant: Samsung Display Co., LTD., Yongin-si (KR)

(72) Inventor: Byeong Kyun CHOI, Yongin-si (KR)

(21) Appl. No.: 18/913,049

(22) Filed: Oct. 11, 2024

(30) Foreign Application Priority Data
Oct. 13, 2023 (KR) 10-2023-0136742

(51) Int. Cl. H01L 33/62; H01L 25/16; H01L 27/12

(52) U.S. Cl. CPC H10H 20/857; H01L 25/167; H10D 86/441; H10D 86/60; H10H 20/0364

(57) ABSTRACT

A display device may include: a substrate; a first conductive pattern and a second conductive pattern on the substrate; a first electrode, a second electrode, a third electrode, and a fourth electrode on the first and second conductive patterns; and a light emitting element on the first and second electrodes. The first electrode may be electrically connected to the first conductive pattern, and the second electrode may be electrically connected to the second conductive pattern. The first conductive pattern may be electrically disconnected from the second electrode and the second conductive pattern, and the second conductive pattern may be electrically disconnected from the first electrode and the first conductive pattern.

### CROSS-REFERENCE TO RELATED APPLICATION

The present application claims priority to and the benefit of Korean Patent Application No. 10-2023-0136742, filed on Oct. 13, 2023 in the Korean Intellectual Property Office, the entire disclosure of which is incorporated herein by reference.

### BACKGROUND

### 1. Field

Aspects of embodiments of the present disclosure relate to a display device and a repairing method thereof.

### 2. Description of the Related Art

Recently, as interest in information displays is increased, research and development of display devices have been continuously conducted.

### SUMMARY

According to aspects of embodiments of the present disclosure, a display device capable of improving reliability by preventing or substantially preventing a dark spot defect of a pixel, and a repairing method of the display device, are provided.

According to one or more embodiments of the present disclosure, a display device includes: a substrate; a first conductive pattern and a second conductive pattern disposed on the substrate, the first conductive pattern and the second conductive pattern being spaced apart from each other; a first electrode, a second electrode, a third electrode, and a fourth electrode disposed on the first and second conductive patterns, the first electrode, the second electrode, the third electrode, and the fourth electrode, being spaced apart from each other; and a light emitting element disposed on the first and second electrodes, wherein the first electrode is electrically connected to the first conductive pattern, and the second electrode is electrically connected to the second conductive pattern, and wherein the first conductive pattern is electrically disconnected from the second electrode and the second conductive pattern, and the second conductive pattern is electrically disconnected from the first electrode and the first conductive pattern.

The first conductive pattern may overlap with the first electrode, the second electrode, and the fourth electrode, and the second conductive pattern may overlap with the first electrode, the second electrode, and the third electrode.

The first electrode and the third electrode may be integrally formed to be electrically connected to each other, and the second electrode and the fourth electrode may be integrally formed to be electrically connected to each other.

The display device may further include: a transistor disposed on the substrate, the transistor being electrically connected to the first and third electrodes; a common line disposed on the substrate, the common line being integrally formed with the second and fourth electrodes to be electrically connected to the second and fourth electrodes; and a power line disposed on the substrate, the power line being electrically connected to the common line, the power line being supplied with a low-potential voltage.

The first electrode may include two or more first sub-electrodes spaced apart from each other, and the second electrode may include two or more second sub-electrodes spaced apart from each other. The first sub-electrodes may be electrically connected to each other, and the second sub-electrodes may be electrically connected to each other.

The display device may further include: a first connection line disposed on the first and second conductive patterns, the first connection line being integrally formed with the first sub-electrodes to be electrically connected to the first sub-electrodes; and a second connection line disposed on the first and second conductive patterns, the second connection line being integrally formed with the second sub-electrodes to be electrically connected to the second sub-electrodes.

The first conductive pattern may be electrically connected to at least one of the first sub-electrodes, and the second conductive pattern may be electrically connected to at least one of the second sub-electrodes.

The display device may further include an insulating layer disposed between the first and second conductive patterns and the first to fourth electrodes, the insulating layer including a first contact portion exposing an end of the first conductive pattern and a second contact portion exposing an end of the second conductive pattern. At least one of the first sub-electrodes may be electrically connected to the first conductive pattern through the first contact portion, and at least one of the second sub-electrodes may be electrically connected to the second conductive pattern through the second contact portion.

The light emitting element may have a horizontal type structure including a first end portion and a second end portion, which are located on a same plane. The light emitting element may include: a semiconductor structure including a first semiconductor layer, an active layer disposed on the first semiconductor layer, and a second semiconductor layer disposed on the active layer; a first contact electrode provided on the semiconductor structure, the first contact electrode being electrically connected to the first semiconductor layer, the first contact electrode being located at the second end portion; and a second contact electrode disposed on the semiconductor structure to be spaced apart from the first contact electrode, the second contact electrode being electrically connected to the second semiconductor layer, the second contact electrode being located at the first end portion.

The first semiconductor layer may include an n-type semiconductor layer doped with an n-type dopant, and the second semiconductor layer may include a p-type semiconductor layer doped with a p-type dopant.

The first end portion of the light emitting element may be electrically connected to the first sub-electrodes, and the second end portion of the light emitting element may be electrically connected to the second sub-electrodes.

The first electrode may be an anode electrode, and the second electrode may be a cathode electrode.

According to one or more embodiments of the present disclosure, a display device includes: a substrate; a first conductive pattern and a second conductive pattern disposed on the substrate, the first conductive pattern and the second conductive pattern being spaced apart from each other; an insulating layer disposed on the first and second conductive patterns, the insulating layer including a first contact portion exposing a first end of the first conductive pattern, a second contact portion exposing a first end of the second conductive pattern, a third contact portion exposing a second end of the first conductive pattern, and a fourth contact portion exposing a second end of the second conductive pattern; a first electrode disposed on the insulating layer, the first electrode including two or more first sub-electrodes; a second electrode disposed on the insulating layer, the second electrode including two or more second sub-electrodes; a third electrode disposed to be spaced apart from the first and second electrodes; a fourth electrode disposed to be spaced apart from the first to third electrodes; and a light emitting element disposed on the first electrode and the second electrode, wherein at least one of the first sub-electrodes is electrically connected to the first end of the first conductive pattern through the first contact portion, and the fourth electrode is electrically connected to the second end of the first conductive pattern through the third contact portion, and wherein at least one of the second sub-electrodes is electrically connected to the first end of the second conductive pattern through the second contact portion, and the third electrode is electrically connected to the second end of the second conductive pattern through the fourth contact portion.

The light emitting element may include a first end portion and a second end portion, which are located on a same plane. The first end portion may be electrically connected to the second sub-electrodes, and the second end portion may be electrically connected to the first sub-electrodes. A p-type semiconductor layer may be located at the first end portion, and an n-type semiconductor layer may be located at the second end portion.

The display device may further include: a transistor disposed on the substrate, the transistor being electrically connected to the third electrode; a common line disposed on the substrate, the common line being integrally formed with the fourth electrode to be electrically connected to the fourth electrode; and a power line disposed on the substrate, the power line being electrically connected to the common line, the power line being supplied with a low-potential voltage. The first sub-electrodes may be electrically connected to the fourth electrode through the first conductive pattern, and the second sub-electrodes may be electrically connected to the third electrode through the second conductive pattern.

The first sub-electrodes may be electrically disconnected from the third electrode, and the second sub-electrodes may be electrically disconnected from the fourth electrode.

The first sub-electrodes may correspond to a cathode electrode, and the second sub-electrode may correspond to an anode electrode.

According to one or more embodiments of the present disclosure, a method of repairing a display device is provided, wherein the display device includes: a substrate; a first conductive pattern and a second conductive pattern disposed on the substrate, the first conductive pattern and the second conductive pattern being spaced apart from each other; a first electrode disposed on the first and second conductive patterns, the first electrode including two or more first sub-electrodes, the first electrode being electrically connected to a first end of the first conductive pattern; a second electrode disposed on the first and second conductive patterns, the second electrode including two or more second sub-electrodes, the second electrode being electrically connected to a first end of the second conductive pattern; a third electrode disposed on the second conductive pattern, the third electrode being electrically connected to the first sub-electrodes, the third electrode overlapping with a second end of the second conductive pattern; a fourth electrode disposed on the first conductive pattern, the fourth electrode being electrically connected to the second sub-electrodes, the fourth electrode overlapping with a second end of the first conductive pattern; and a light emitting element electrically connected to the first sub-electrodes and the second sub-electrodes, and wherein the method comprises: electrically disconnecting the first sub-electrodes and the third electrode from each other and electrically disconnecting the second sub-electrodes and the fourth electrode, using a laser, in a case in which the light emitting element is a defective light emitting element; and electrically connecting the second end of the first conductive pattern and the fourth electrode to each other by irradiating laser onto a top of an overlapping area of the first conductive pattern and the fourth electrode and then removing a portion of an insulating layer between the first conductive pattern and the fourth electrode, and electrically connecting the second end of the second conductive pattern and the third electrode to each other by irradiating a laser onto a top of an overlapping area of the second conductive pattern and the third electrode and then removing another portion of the insulating layer between the second conductive pattern and the third electrode.

The defective light emitting element may include a first end portion and a second end portion, which are located on a same plane. The first end portion may be electrically connected to the second sub-electrodes and the fourth electrode, and the second end portion may be electrically connected to the first sub-electrodes and the third electrode. A p-type semiconductor layer may be located at the first end portion, and an n-type semiconductor layer may be located at the second end portion.

The display device may further include: a transistor disposed on the substrate, the transistor being electrically connected to the third electrode; a common line disposed on the substrate, the common line being integrally formed with the fourth electrode to be electrically connected to the fourth electrode; and a power line disposed on the substrate, the power line being electrically connected to the common line, the power line being supplied with a low-potential voltage. The first sub-electrodes may be electrically connected to the fourth electrode through the first conductive pattern, and the second sub-electrodes may be electrically connected to the third electrode through the second conductive pattern.

### BRIEF DESCRIPTION OF DRAWINGS

Some example embodiments will now be described more fully herein with reference to the accompanying drawings; however, the present disclosure may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It is to be understood that in case that an element is referred to as being “between” two elements, it may be the only element between the two elements, or one or more intervening elements may also be present. Like reference numerals refer to like elements throughout.

FIG. 1 is a schematic plan view illustrating a display device in accordance with an embodiment of the present disclosure.

FIG. 2 is a schematic cross-sectional view illustrating a display panel shown in FIG. 1.

FIG. 3 is a schematic circuit diagram illustrating an electrical connection relationship of components included in each of pixels shown in FIG. 1.

FIG. 4 is a schematic plan view illustrating a sub-pixel in accordance with an embodiment of the present disclosure.

FIG. 5 is a schematic cross-sectional view taken along the line I-I′ shown in FIG. 4.

FIG. 6 is a schematic cross-sectional view taken along the lines II-II′ and III-III′ shown in FIG. 4.

FIG. 7 is a schematic plan view illustrating a state in which a light emitting element is transferred in the sub-pixel shown in FIG. 4.

FIG. 8 is a schematic cross-sectional view taken along the line IV-IV′ shown in FIG. 7.

FIG. 9 is a schematic cross-sectional view illustrating a light emitting element shown in FIG. 8.

FIG. 10 illustrates a sub-pixel in accordance with an embodiment of the present disclosure, and is a schematic cross-sectional view corresponding to the line IV-IV′ shown in FIG. 7.

FIG. 11 illustrates a sub-pixel including a defective light emitting element, and is a schematic cross-sectional view corresponding to the line IV-IV′ shown in FIG. 7.

FIGS. 12 and 13 are schematic plan views illustrating a method of repairing the defective light emitting element shown in FIG. 11.

FIG. 14A is a schematic cross-sectional view taken along the line V-V′ shown in FIG. 13.

FIG. 14B is a schematic enlarged cross-sectional view of a region “EA1” shown in FIG. 14A.

FIG. 15A is a schematic cross-sectional view taken along the line VI-VI′ shown in FIG. 13.

FIG. 15B is a schematic enlarged cross-sectional view of a region “EA2” shown in FIG. 15A.

### DETAILED DESCRIPTION

The present disclosure may apply various changes and different shapes, and, therefore, only some particular examples are illustrated herein. However, the examples are not limited to certain shapes but apply to various changes and equivalent materials and replacement thereof. The drawings included may be illustrated such that the figures are expanded for better understanding.

Like numbers refer to like elements throughout. In the drawings, the thickness of certain lines, layers, components, elements, or features may be exaggerated for clarity. It is to be understood that, although the terms “first,” “second,” etc. may be used herein to describe various elements, these elements are not to be limited by these terms. These terms are used to distinguish one element from another element. Thus, a “first” element discussed below could also be termed a “second” element without departing from the teachings of the present disclosure. As used herein, the singular forms are intended to include the plural forms as well, unless the context clearly indicates otherwise.

It is to be further understood that the terms “includes” and/or “including,” as used in this specification, specify the presence of stated features, integers, steps, operations, elements, and/or components, but do not preclude the presence and/or addition of one or more other features, integers, steps, operations, elements, components, and/or groups thereof. Further, an expression that an element such as a layer, region, substrate, or plate is placed “on” or “above” another element indicates not only a case in which the element is placed “directly on” or “just above” the other element, but also a case in which a further element is interposed between the element and the other element. Also, an expression that an element such as a layer, region, substrate or plate is placed “beneath” or “below” another element indicates not only a case in which the element is placed “directly beneath” or “just below” the other element, but also a case where a further element is interposed between the element and the other element.

Herein, some example embodiments of the present disclosure and items required for those skilled in the art to easily understand the content of the present disclosure will be described in further detail with reference to the accompanying drawings. In the following description, singular forms in the present disclosure are intended to include the plural forms as well, unless the context clearly indicates otherwise.

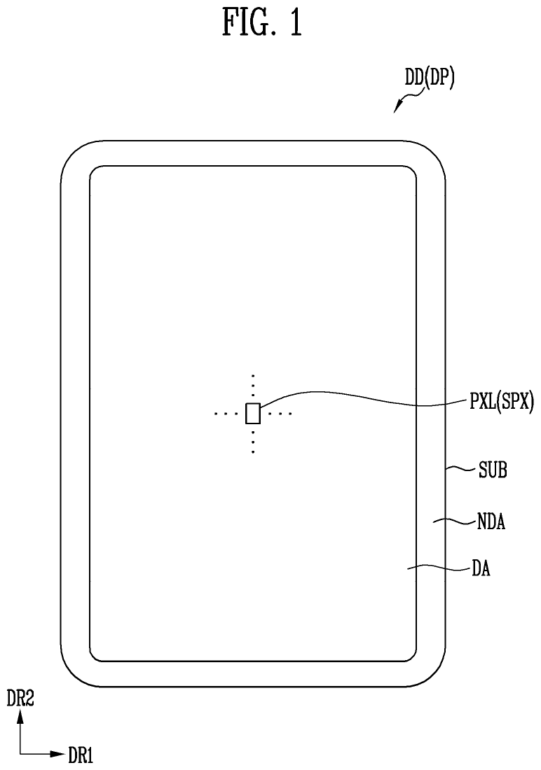

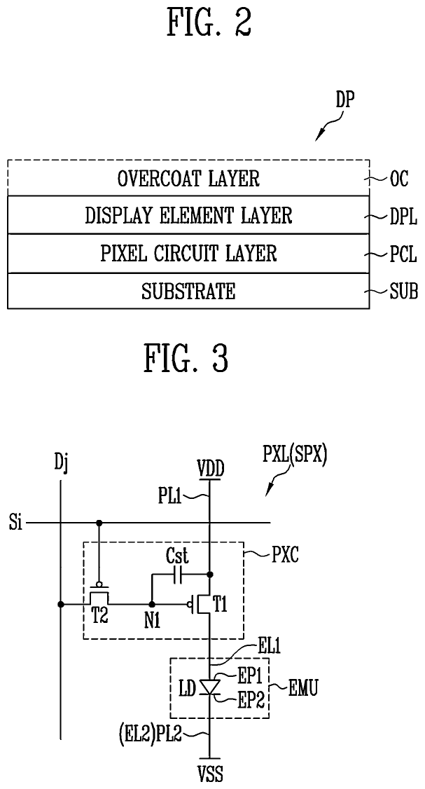

FIG. 1 is a schematic plan view illustrating a display device DD in accordance with an embodiment of the present disclosure. FIG. 2 is a schematic cross-sectional view illustrating a display panel DP shown in FIG. 1.

In FIGS. 1 and 2, for convenience of description, a structure of the display device DD, e.g., a display panel DP provided in the display device DD is schematically illustrated based on a display area DA in which an image is displayed.

Referring to FIGS. 1 and 2, the display panel DP (or the display device DD) in accordance with an embodiment of the present disclosure may be provided in any of various shapes. For example, the display panel DP may be provided in a rectangular plate shape having two pairs of sides parallel to each other, but the present disclosure is not limited thereto. In the case in which the display panel DP is provided in the rectangular plate shape, any one pair of sides among the two pairs of sides may be provided longer than the other pair of sides. In FIG. 1, an extension direction of a long side is indicated as a second direction DR2, and an extension direction of a short side is indicated as a first direction DR1.

In an embodiment, at least a portion of the display panel DP may have flexibility, and be folded at the portion having flexibility. However, the present disclosure is not limited thereto.

The display panel DP may display an image. A self-luminous display panel or a non-luminous display panel may be used as the display panel DP.

The display panel DP may include a substrate SUB and pixels PXL (or sub-pixels SPX) provided on the substrate SUB.

The substrate SUB may include a transparent insulating material to enable light to be transmitted therethrough, but the present disclosure is not limited thereto. The substrate SUB may be a rigid substrate or a flexible substrate.

The rigid substrate may be, for example, any of a glass substrate, a quartz substrate, a glass ceramic substrate, and a crystalline glass substrate.

The flexible substrate may be any of a film substrate and a plastic substrate, which may include a polymer organic material. For example, the flexible substrate may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate.

An area of the substrate SUB may be provided as the display area DA such that the pixels PXL are disposed therein, and another area on the substrate SUB may be provided as a non-display area NDA. For example, the substrate SUB may include the display area DA including pixel areas in which the respective pixels PXL (or the respective sub-pixels SPX) are disposed and the non-display area NDA disposed at the periphery of the display area DA (or adjacent to the display area DA).

The non-display area NDA may be located adjacent to the display area DA. The non-display area NDA may be provided at at least one side of the display area DA. For example, the non-display area NDA may surround a circumference (or edge) of the display area DA. A line unit connected to each pixel PXL and a driving unit which is connected to the line unit and drives the pixel PXL may be provided in the non-display area NDA.

The pixel PXL may be provided in the display area DA of the substrate SUB. The pixel PXL may include a light emitting element emitting white light and/or colored light and a pixel circuit for driving the light emitting element. The pixel circuit may include at least one transistor electrically connected to the light emitting element. The pixel PXL may emit light of a color among red, green, and blue, but the present disclosure is not limited thereto. For example, the pixel PXL may emit light of a color among cyan, magenta, yellow, and white.

In an embodiment, a plurality of pixels PXL may be provided to be arranged in a matrix form along rows extending in a first direction DR1 and columns extending in a second direction DR2 intersecting the first direction DR1. However, an arrangement form of the pixels PXL is not particularly limited, and the pixels PXL may be arranged in various forms. In some embodiments, in a case in which each of the pixels PXL is provided in plural, the pixels PXL may be provided to different areas (or sizes). For example, in a case in which the pixels PXL have different colors of lights emitted therefrom, the pixels PXL may be provided to have different areas (or sizes) or different shapes with respect to the different colors.

The driving unit may provide a signal (e.g., a predetermined signal) and a voltage (e.g., a predetermined voltage) to each pixel PXL through the line unit, thereby controlling driving of the pixel PXL.

The display panel DP (or the pixel PXL) may include a substrate SUB, a pixel circuit layer PCL, a display element layer DPL, and an overcoat layer OC.

The pixel circuit layer PCL may be provided on the substrate SUB, and include a transistor and signal lines connected to the transistor. For example, the transistor may have a form in which a semiconductor pattern and a gate electrode are sequentially stacked with an insulating layer interposed therebetween. The semiconductor pattern may include amorphous silicon, poly-silicon, low temperature poly-silicon, an organic semiconductor, and/or an oxide semiconductor. The gate electrode may include any of aluminum, copper, titanium, and molybdenum, but the present disclosure is not limited thereto. Also, the pixel circuit layer PCL may include at least one insulating layer.

The display element layer DPL may be disposed on the pixel circuit layer PCL. The display element layer DPL may include a light emitting element emitting light.

The overcoat layer OC may be selectively disposed over the display element layer DPL.

The overcoat layer OC may be provided to cover the display element layer DPL. Thus, the overcoat layer OC can protect the display element layer DPL from an external impact.

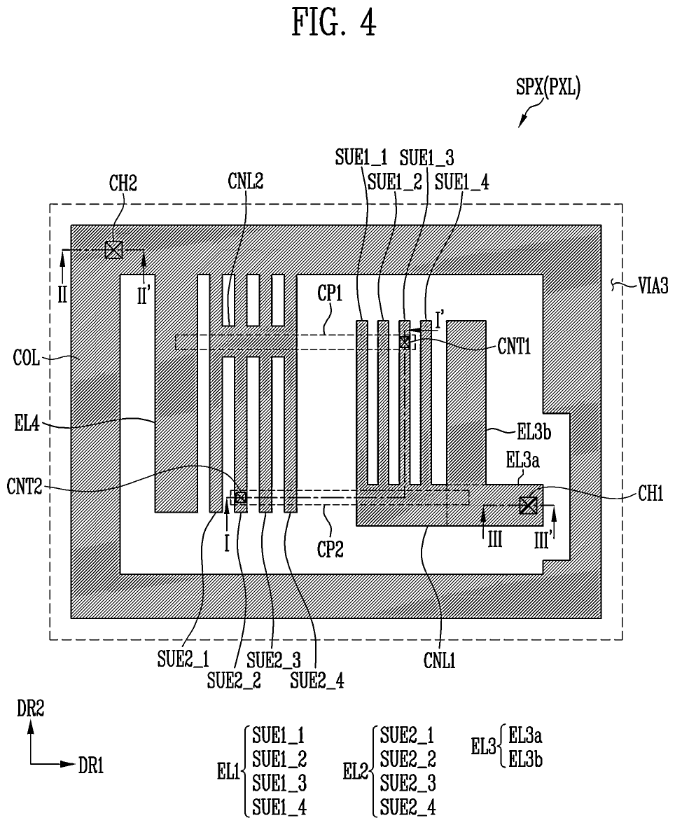

FIG. 3 is a schematic circuit diagram illustrating an electrical connection relationship of components included in each of the pixels PXL shown in FIG. 1.

For convenience of description, a pixel PXL (or a sub-pixel SPX) located on an ith pixel row (or ith horizontal line) and a jth pixel column will be illustrated in FIG. 3 (i and j are natural numbers).

Referring to FIGS. 1 to 3, the pixel PXL (or the sub-pixel SPX) may include a pixel circuit PXC and a light emitting unit EMU.

The light emitting unit EMU may include a light emitting element LD connected between a first power line PL1 supplied with a voltage of a first driving power source VDD and a second power line PL2 supplied with a voltage of a second driving power source VSS. For example, the light emitting unit EMU may include a first electrode EL1 connected to the first driving power source VDD via the pixel circuit PXC and the first power line PL1, a second electrode EL2 connected to the second driving power source VSS via the second power line PL2, and the light emitting element LD connected between the first electrode EL1 and the second electrode EL2. In an embodiment, the first electrode EL1 may be an anode electrode, and the second electrode EL2 may be a cathode electrode.

The light emitting element LD may include a first end portion EP1 electrically connected to the first electrode EL1 and a second end portion EP2 electrically connected to the second electrode EL2. The voltage of the first driving power source VDD and the voltage of the second driving power source VSS may have different potentials. For example, the voltage of the first driving power source VDD may be a high-potential voltage, and the voltage of the second driving power source VSS may be a low-potential voltage. A potential difference between the first and second driving power sources VDD and VSS may be set equal to or higher than a threshold voltage of the light emitting element LD during an emission period of the pixel PXL.

As described above, the light emitting element LD may constitute an effective light source of the light emitting unit EMU.

The light emitting element LD may emit light with a luminance corresponding to a driving current supplied through the pixel circuit PXC. For example, the pixel circuit PXC may supply, to the light emitting unit EMU, a driving current corresponding to a grayscale value of corresponding frame data during each frame period. The driving current supplied to the light emitting unit EMU may flow through the light emitting element LD. Accordingly, the light emitting unit EMU can emit light while the light emitting element LD emits light with a luminance corresponding to the driving current.

In a case in which a pixel PXL (or a sub-pixel SPX) is located on an ith pixel row and a jth pixel column in the display area DA, a pixel circuit PXC of the pixel PXL may be electrically connected to an ith scan line Si and a jth data line Dj.

The pixel circuit PXC may include a first transistor T1, a second transistor T2, and a storage capacitor Cst.

The first transistor T1 is a driving transistor for controlling a driving current applied to the light emitting element LD, and may be electrically connected between the first power line PL1 to which the voltage of the first driving power source VDD is supplied and the light emitting element LD. A first terminal of the first transistor T1 may be electrically connected to the voltage of the first driving power source VDD through the first power line PL1, a second terminal of the first transistor T1 may be electrically connected to the light emitting element LD, and a gate electrode of the first transistor T1 may be electrically connected to a first node N1. The first transistor T1 may be turned on according to a voltage applied to the first node N1. The first transistor T1 may be designated as the driving transistor.

The second transistor T2 is a switching transistor for selecting a pixel PXL in response to a scan signal and activating the pixel PXL, and may be electrically connected between a jth data line Dj and the first node N1. A first terminal of the second transistor T2 may be electrically connected to the jth data line Dj, a second terminal of the second transistor T2 may be electrically connected to the first node N1 (or the gate electrode of the first transistor T1), and a gate electrode of the second transistor T2 may be electrically connected to an ith scan line Si.

The second transistor T2 may be turned on in a case in which a scan signal having a gate-on voltage (e.g., a low level voltage) is supplied from the ith scan line Si, to electrically connect the jth data line Dj and the first node N1 to each other. A data signal of a corresponding frame may be supplied to the jth data line Dj. Accordingly, the data signal may be transferred to the first node N1. The data signal transferred to the first node N1 may be charged in the storage capacitor Cst.

A first electrode of the storage capacitor Cst may be electrically connected to a node (or the first power line PL1) to which the voltage of the first driving power source VDD is supplied, and a second electrode of the storage capacitor Cst may be electrically connected to the first node N1. The storage capacitor Cst may charge a voltage corresponding to the data signal supplied to the first node N1, and maintain the charged voltage until a data signal of a next frame is supplied.

In FIG. 3, the pixel circuit PXC is illustrated, which includes the second transistor T2 for transferring a data signal to the pixel PXL (or the sub-pixel SPX), the storage capacitor Cst for storing the data signal, and the first transistor T1 for supplying a driving current corresponding to the data signal to the light emitting element LD. However, the present disclosure is not limited thereto, and a structure of the pixel circuit PXC may be variously modified according to embodiments. For example, the pixel circuit PXC may additionally further include at least one transistor element such as a transistor element for compensating for a threshold voltage of the first transistor T1, a transistor element for initializing the first node N1, and/or a transistor element for controlling an emission time of the light emitting element LD, or other circuit elements, such as a boosting capacitor for boosting the voltage of the first node N1.

In an embodiment, for convenience of description, a lateral direction (or X-axis direction) on a plane is indicated as a first direction DR1, a longitudinal direction (or Y-axis direction) on the plane is indicated as a second direction DR2, and a direction on a section is indicated as a third direction DR3.

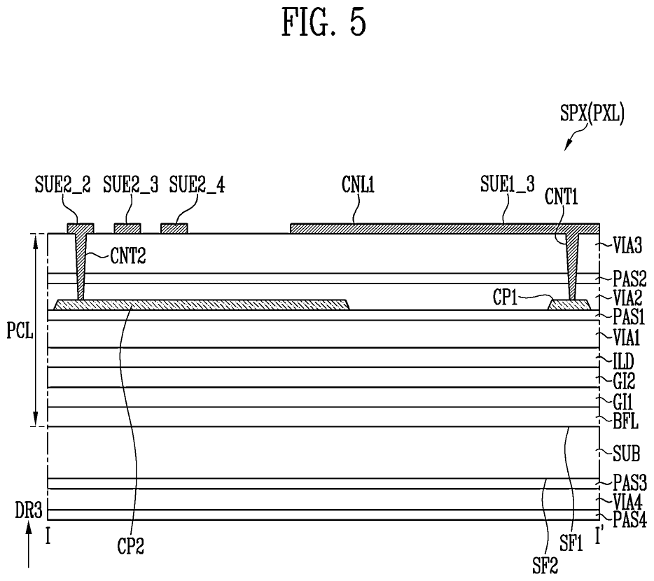

FIG. 4 is a schematic plan view illustrating a sub-pixel SPX in accordance with an embodiment of the present disclosure.

In FIG. 4, for convenience of description, a first conductive pattern CP1 and a second conductive pattern CP2 among components disposed under a third via layer VIA3 are illustrated.

Referring to FIGS. 1 to 4, the sub-pixel SPX (or pixel PXL) may include a first electrode EL1, a second electrode EL2, a third electrode EL3, a fourth electrode EL4, and a common line COL, which are disposed on the third via layer VIA3. Also, the sub-pixel SPX may include the first conductive pattern CP1 and the second conductive pattern CP2, which are disposed under the third via layer VIA3.

In an embodiment, the common line COL may have a closed-loop shape around (e.g., surrounding) the first to fourth electrodes EL1, EL2, EL3, and EL4 in an area of the display area DA in which the sub-pixel SPX is disposed. However, the present disclosure is not limited thereto, and the common line COL may be provided in various shapes. The common line COL may be electrically connected to the second power line PL2 of the pixel PXL described with reference to FIG. 3. Therefore, the voltage of the second driving power source VSS may be supplied to the common line COL.

The first electrode EL1 may be disposed to be spaced apart from the common line COL. The first electrode EL1 may be integrally formed with the third electrode EL3. The first electrode EL1 and the third electrode EL3 may be electrically connected to each other. In an embodiment, the first electrode EL1 may have a bar shape extending in the second direction DR2, but the present disclosure is not limited thereto.

In an embodiment, the first electrode EL1 may include at least two first sub-electrodes. For example, the first electrode EL1 may include four first sub-electrodes. The four first sub-electrodes may include a (1-1)th sub-electrode SUE1_1, a (1-2)th sub-electrode SUE1_2, a (1-3)th sub-electrode SUE1_3, and a (1-4)th sub-electrode SUE1_4. The (1-1)th sub-electrode SUE1_1, the (1-2)th sub-electrode SUE1_2, the (1-3)th sub-electrode SUE1_3, and the (1-4)th sub-electrode SUE1_4 may be arranged along the first direction DR1, and extend in the second direction DR2. The (1-1)th sub-electrode SUE1_1, the (1-2)th sub-electrode SUE1_2, the (1-3)th sub-electrode SUE1_3, and the (1-4)th sub-electrode SUE1_4 may be electrically connected to each other through a first connection line CNL1. The (1-1)th sub-electrode SUE1_1, the (1-2)th sub-electrode SUE1_2, the (1-3)th sub-electrode SUE1_3, and the (1-4)th sub-electrode SUE1_4 may have a bar shape extending along the second direction DR2 from the first connection line CNL1.

The first connection line CNL1 may extend in the first direction DR1, and be located between adjacent first sub-electrodes to electrically connect the first sub-electrodes to each other. The first connection line CNL1 may be located, for example, between the (1-1)th sub-electrode SUE1_1 and the (1-2)th sub-electrode SUE1-2, between the (1-2)th sub-electrode SUE1-2 and the (1-3)th sub-electrode SUE1_3, and between the (1-3)th sub-electrode SUE1_3 and the (1-4)th sub-electrode SUE1_4. In an embodiment, the first connection line CNL1 may be integrally formed with the (1-1)th sub-electrode SUE1_1, the (1-2)th sub-electrode SUE1_2, the (1-3)th sub-electrode SUE1_3, and the (1-4)th sub-electrode SUE1_4. In an embodiment, the first connection line CNL1 may be integrally formed with a first portion EL3a of the third electrode EL3.

In an embodiment, the (1-1)th sub-electrode SUE1_1, the (1-2)th sub-electrode SUE1_2, the (1-3)th sub-electrode SUE1_3, and the (1-4)th sub-electrode SUE1_4 may have a same width, but the present disclosure is not limited thereto. In some embodiments, the (1-1)th sub-electrode SUE1_1, the (1-2)th sub-electrode SUE1_2, the (1-3)th sub-electrode SUE1_3, and the (1-4)th sub-electrode SUE1_4 may have different widths. In an embodiment, the first connection line CNL1 may have a width different from the width of the (1-1)th to (1-4)th sub-electrodes SUE1_1 to SUE1_4.

The second electrode EL2 may branch off along the second direction DR2 from the common line COL. In an embodiment, the second electrode EL2 may be integrally formed with the common line COL to be electrically connected to the common line COL. The second electrode EL2 may have a bar shape extending in the second direction DR2, but the present disclosure is not limited thereto. In an embodiment, the common line COL is electrically connected to the second power line PL2 through a second contact hole CH2, such that the second electrode EL2 may be electrically connected to the second power line PL2. In an embodiment, the second electrode EL2 may be a cathode electrode electrically connected to the second terminal EP2 of the light emitting element LD.

In an embodiment, the second electrode EL2 may include at least two second sub-electrodes. For example, the second electrode EL2 may include four second sub-electrodes. The four second sub-electrodes may include a (2-1)th sub-electrode SUE2_1, a (2-2)th sub-electrode SUE2_2, a (2-3)th sub-electrode SUE2_3, and a (2-4)th sub-electrode SUE2_4. The (2-1)th sub-electrode SUE2_1, the (2-2)th sub-electrode SUE2_2, the (2-3)th sub-electrode SUE2_3, and the (2-4)th sub-electrode SUE2_4 may be arranged along the first direction DR1, and be electrically connected to each other through a second connection line CNL2.

The second connection line CNL2 may extend in the first direction DR1, and be located between adjacent second sub-electrodes to electrically connect the second sub-electrodes to each other. The second connection line CNL2 may be located, for example, between the (2-1)th sub-electrode SUE2_1 and the (2-2)th sub-electrode SUE2_2, between the (2-2)th sub-electrode SUE2_2 and the (2-3)th sub-electrode SUE2_3, and between the (2-3)th sub-electrode SUE2_3 and the (2-4)th sub-electrode SUE2_4. In an embodiment, the second connection line CNL2 may be integrally formed with the (2-1)th sub-electrode SUE2_1, the (2-2)th sub-electrode SUE2_2, the (2-3)th sub-electrode SUE2_3, and the (2-4)th sub-electrode SUE2_4.

In an embodiment, the (2-1)th sub-electrode SUE2_1, the (2-2)th sub-electrode SUE2_2, the (2-3)th sub-electrode SUE2_3, and the (2-4)th sub-electrode SUE2_4 may have a same width, but the present disclosure is not limited thereto. In some embodiments, the (2-1)th sub-electrode SUE2_1, the (2-2)th sub-electrode SUE2_2, the (2-3)th sub-electrode SUE2_3, and the (2-4)th sub-electrode SUE2_4 may have different widths. The second connection line CNL2 may have a width different from the width of the (2-1)th to (2-4)th sub-electrodes SUE2_1 to SUE2_4.

In a plan view, the (1-1)th sub-electrode SUE1_1 and the (2-4)th sub-electrode SUE2_4 may be disposed to face each other in the first direction DR1, but the present disclosure is not limited thereto.

The third electrode EL3 may be disposed to be spaced apart from the first electrode EL1, the second electrode EL2, the fourth electrode EL4, and the common line COL. The third electrode EL3 may be electrically connected to the first electrode EL1 through the first connection line CNL1. In an embodiment, the third electrode EL3, the first connection line CNL1, and the first electrode EL1 may be integrally formed.

The third electrode EL3 may be electrically connected to a partial component, e.g., the first transistor T1 of the pixel circuit PXC described with reference to FIG. 3 through a first contact hole CH1. In an embodiment, the third electrode EL3 is electrically connected to the first electrode EL1 through the first connection line CNL1, such that the first electrode EL1 may be electrically connected to the pixel circuit PXC. In an embodiment, the first electrode EL1 may be an anode electrode electrically connected to the first end portion EP1 of the light emitting element LD.

The third electrode EL3 may include the first portion EL3a extending along the first direction DR1 and a second portion EL3b extending along the second direction DR2. In an embodiment, a width of the second portion EL3b may be greater than the width of the first sub-electrodes, but the present disclosure is not limited thereto.

The fourth electrode EL4 may be disposed to be spaced apart from the first to third electrodes EL1, EL2, and EL3. The fourth electrode EL4 may branch off along the second direction DR2 from the common line COL. In an embodiment, the common line COL, the second electrode EL2, and the fourth electrode EL4 may be integrally formed. The fourth electrode EL4 may be electrically connected to the second power line PL2.

In an embodiment, the fourth electrode EL4 may have a bar shape extending in the second direction DR2, but the present disclosure is not limited thereto. In an embodiment, a width of the fourth electrode EL4 may be greater than the width of the second sub-electrodes, but the present disclosure is not limited thereto. In some embodiments, a width of each of the second sub-electrodes may be greater than the width of the fourth electrode EL4.

The first conductive pattern CP1 and the second conductive pattern CP2 may be disposed under the first to fourth electrodes EL1 to EL4 and the common line COL. For example, the first conductive pattern CP1 and the second conductive pattern CP2 may be disposed under the first to fourth electrodes EL1 to EL4 and the common line COL with the third via layer VIA3 interposed therebetween.

The first conductive pattern CP1 may extend in the first direction DR1, and be disposed to be spaced apart from the second conductive pattern CP2. The first conductive pattern CP1 may serve as a first bridge pattern electrically connecting the first electrode EL1 and the fourth electrode EL4 to each other through laser irradiation or the like in a process of repairing a dark spot defect of the sub-pixel SPX, which occurs as the light emitting element LD is connected in a reverse direction. In an embodiment, the first conductive pattern CP1 may be electrically connected to the first electrode EL1 through a first contact portion CNT1. For example, an end (e.g., a “right end portion” in a plan view) of the first conductive pattern CP1 may be electrically connected to the (1-3)th sub-electrode SUE1_3 through the first contact portion CNT1 penetrating some insulating layers including the third via layer VIA3. The first conductive pattern CP1, the first electrode EL1 including the (1-3)th sub-electrode SUE1_3, and the third electrode EL3 may be electrically connected to each other. In an embodiment, the first conductive pattern CP1 may overlap with each of the first electrode EL1, the second electrode EL2, and the fourth electrode EL4. In an embodiment, the first conductive pattern CP1 may not overlap with the third electrode EL3, but the present disclosure is not limited thereto. In some embodiments, the first conductive pattern CP1 may also overlap with the third electrode EL3.

The second conductive pattern CP2 may extend in the first direction DR1, and be disposed to be spaced apart from the first conductive pattern CP1. The second conductive pattern CP2 may serve as a second bridge pattern electrically connecting the second electrode EL2 and the third electrode EL3 through laser irradiation or the like in a process of repairing a dark spot defect of the sub-pixel SPX, which occurs as the light emitting element LD is connected in a reverse direction. In an embodiment, the second conductive pattern CP2 may be electrically connected to the second electrode EL2 through a second contact portion CNT2. For example, an end (e.g., a “left end portion” in a plan view) of the second conductive pattern CP2 may be electrically connected to the (2-2)th sub-electrode SUE2_2 of the second electrode EL2 through the second contact portion CNT2 penetrating some insulating layers including the third via layer VIA3. The second conductive pattern CP2, the second electrode EL2 including the (2-2)th sub-electrode SUE2_2, the fourth electrode EL4, and the common line COL may be electrically connected to each other. In an embodiment, the second conductive pattern CP2 may overlap with each of the first electrode EL1, the second electrode EL2, and the third electrode EL3. In an embodiment, the second conductive pattern CP2 may not overlap with the fourth electrode EL4, but the present disclosure is not limited thereto. In some embodiments, the second conductive pattern CP2 may also overlap with the fourth electrode EL4.

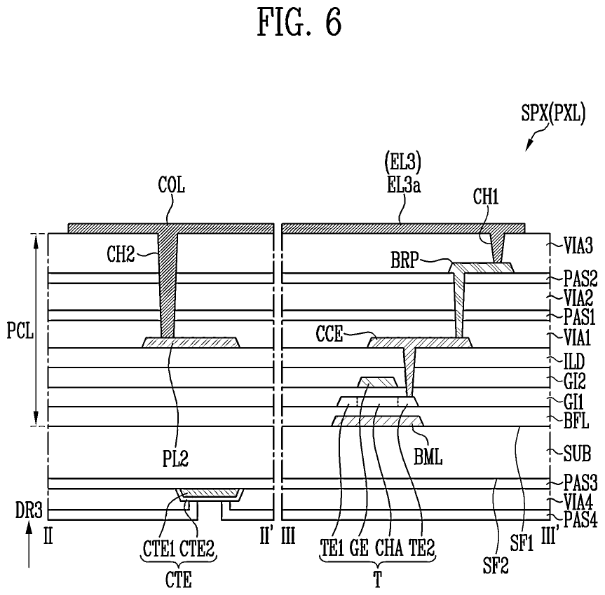

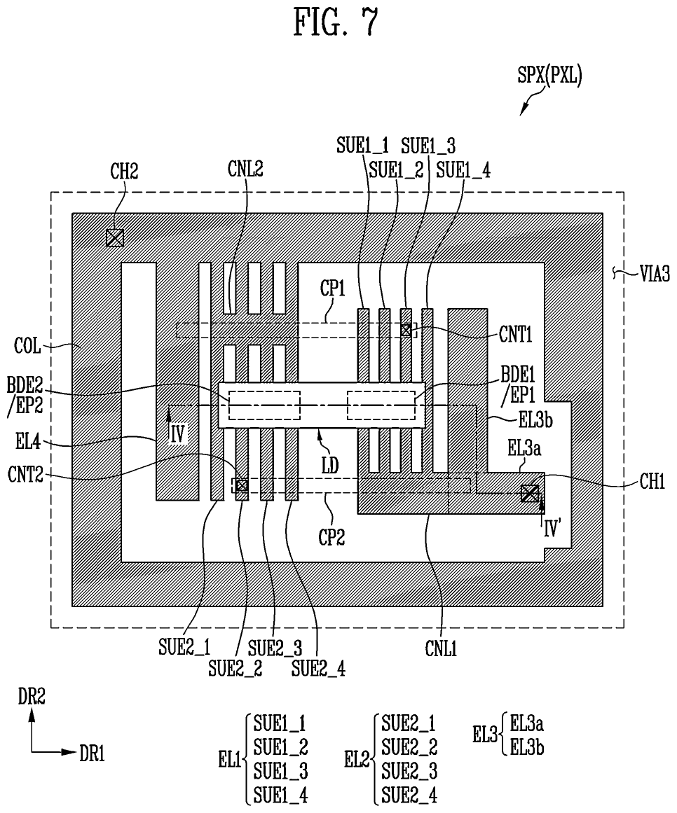

Herein, a stacked structure (or cross-sectional structure) of the sub-pixel SPX (or the pixel PXL) in accordance with the above-described embodiment will be mainly described with reference to FIGS. 5 and 6.

FIG. 5 is a schematic cross-sectional view taken along the line I-I′ shown in FIG. 4; and FIG. 6 is a schematic cross-sectional view taken along the lines II-II′ and III-III′ shown in FIG. 4.

In FIGS. 5 and 6, one sub-pixel SPX (or one pixel PXL) is illustrated for convenience of description such that each electrode is illustrated as an electrode having a signal layer and each insulating layer is illustrated as an insulating layer provided as a single layer, but the present disclosure is not limited thereto.

Referring to FIGS. 1 to 6, the sub-pixel SPX (or the pixel PXL) may include a substrate SUB, a pixel circuit layer PCL disposed on the substrate SUB, and electrodes disposed on the pixel circuit layer PCL.

The substrate SUB may include a transparent insulating material to enable light to be transmitted therethrough. The substrate SUB may be a rigid substrate or a flexible substrate. The substrate SUB may include a first surface SF1 and a second surface SF2, which face away from each other in the third direction DR3. The first surface SF1 may be a mounting surface on which the light emitting element LD is mounted, and the second surface SF2 may be a surface on which an intermediate electrode CTE electrically connected to a flexible film (not shown) is disposed.

In the sub-pixel SPX, a third passivation layer PAS3, a fourth via layer VIA4, and a fourth passivation layer PAS4, which are sequentially stacked in the opposite direction of the third direction DR3, may be disposed on the second surface SF2 of the substrate SUB.

The third passivation layer PAS3 may be located on the second surface SF2 of the substrate SUB, protect the second surface SF2 of the substrate SUB, and planarize the second surface of the substrate SUB. In an embodiment, the third passivation layer PAS3 may be an inorganic insulating layer including an inorganic material. In an embodiment, the third passivation layer PAS3 may include at least one of silicon nitride (SiNₓ), silicon oxide (SiOₓ), silicon oxynitride (SiOₓN_{y}), and aluminum oxide (AIOₓ).

The intermediate electrode CTE may be disposed on the third passivation layer PAS3. The intermediate electrode CTE may supply a voltage or a signal, which is received from the flexible film, to a side surface connection line (not shown) through a lead line. The intermediate electrode CTE may be electrically connected to the flexible film through a conductive member (or connection film).

In an embodiment, the intermediate electrode CTE may include a first intermediate electrode CTE1 and a second intermediate electrode CTE2. The first intermediate electrode CTE1 may be disposed on a surface (or bottom surface) of the third passivation layer PAS3. The first intermediate electrode CTE1 may be a single layer or a multi-layer, which is made of any of molybdenum, aluminum, chromium, gold, titanium, nickel, neodymium, copper, or any alloy thereof. The second intermediate electrode CTE2 may be disposed on a surface (or bottom surface) of the first intermediate electrode CTE1. The second intermediate electrode CTE2 may include a transparent conductive material (TCO), such as ITO or IZO.

The fourth via layer VIA4 may be disposed on the third passivation layer PAS3 and a portion of the intermediate electrode CTE. In an embodiment, the fourth via layer VIA4 may be an organic insulating layer including an organic material. In an embodiment, the fourth via layer VIA4 may include at least one of acrylic resin, epoxy resin, phenolic resin, polyamide resin, polyimide resin, unsaturated polyester resin, poly-phenylene ether resin, poly-phenylene sulfide resin, and benzocyclobutene resin. The fourth via layer VIA4 may planarize the second surface SF2 of the substrate SUB.

The fourth passivation layer PAS4 may be disposed on the fourth via layer VIA4 and the intermediate electrode CTE to protect the intermediate electrode CTE. In an embodiment, the fourth passivation layer PAS4 may include a same material as the third passivation layer PAS3 or include a suitable material among the materials described, for example, as a material constituting the third passivation layer PAS3.

The pixel circuit layer PCL may be provided and/or formed on the first surface SF1 of the substrate SUB.

The pixel circuit PXC may be disposed in the pixel circuit layer PCL. The pixel circuit layer PCL may include at least one insulating layer disposed on the first surface SF1 of the substrate SUB. For example, the pixel circuit layer PCL may include a buffer layer BFL, a first gate insulating layer GI1, a second gate insulating layer GI2, an interlayer insulating layer ILD, a first via layer VIA1, a first passivation layer PAS1, a second via layer VIA2, a second passivation layer PAS2, and a third via layer VIA3, which are sequentially stacked along the third direction DR3 on the first surface SF1 of the substrate SUB.

The buffer layer BFL may be disposed on the first surface SF1 of the substrate SUB. The buffer layer BFL may prevent or substantially prevent an impurity from being diffused into a transistor T. In an embodiment, the buffer layer BFL may be an inorganic insulating layer including an inorganic material. For example, the buffer layer BFL may include at least one of silicon nitride (SiNₓ), silicon oxide (SiOₓ), and silicon oxynitride (SiOₓN_{y}), or include at least one of metal oxides, such as aluminum oxide (AIOₓ). In an embodiment, the buffer layer BFL may be provided as a single layer, but be provided as a multi-layer including at least two layers. In a case in which the buffer layer BFL is provided as the multi-layer, the layers may be formed of a same material or be formed of different materials. However, in an embodiment, the buffer layer BFL may be omitted according to a material of the substrate SUB, a process condition, and the like.

The first gate insulating layer GI1 may be disposed on the buffer layer BFL, but the present disclosure is not limited thereto. In some embodiments, the first gate insulating layer GI1 may be partially disposed on the buffer layer BFL. The first gate insulating layer GI1 may include a same material as the above-described buffer layer BFL or include a suitable material among the materials, for example, described as the material constituting the buffer layer BFL.

The second gate insulating layer GI2 may be disposed on the first gate insulating layer GI1, but the present disclosure is not limited thereto. In some embodiments, the second gate insulating layer GI2 may be partially disposed on the first gate insulating layer GI1. In an embodiment, the second gate insulating layer GI2 may include a same material as the first gate insulating layer GI1. For example, the second gate insulating layer GI2 may be an inorganic insulating layer including an inorganic material.

The interlayer insulating layer ILD may be provided and/or formed on the second gate insulating layer GI2. In an embodiment, the interlayer insulating layer ILD may include a same material as the second gate insulating layer GI2 or include a suitable material among the materials, for example, as the material constituting the second gate insulating layer GI2.

The first via layer VIA1 may be provided and/or formed on the interlayer insulating layer ILD. The first via layer VIA1 may be an inorganic insulating layer including an inorganic material or an organic insulating layer including an organic material. The inorganic insulating layer may include, for example, at least one of silicon nitride (SiNₓ), silicon oxide (SiOₓ), silicon oxynitride (SiOₓN_{y}), and aluminum oxide (AIOₓ). The organic insulating layer may include, for example, at least one of acrylic resin, epoxy resin, phenolic resin, polyamide resin, polyimide resin, unsaturated polyester resin, poly-phenylene ether resin, poly-phenylene sulfide resin, and benzocyclobutene resin. The first via layer VIA1 may have a flat surface to reduce a step difference occurring due to components disposed thereunder. The first via layer VIA1 may be an organic insulating layer including an organic material.

In an embodiment, the first passivation layer PAS1 may be entirely provided and/or formed on the first via layer VIA1. In an embodiment, the first passivation layer PAS1 may be an inorganic insulating layer including an inorganic material. The passivation layer PAS1 may include at least one of silicon nitride (SiNₓ), silicon oxide (SiOₓ), silicon oxynitride (SiOₓN_{y}), and aluminum oxide (AIOₓ).

In an embodiment, the second via layer VIA2 may be entirely provided and/or formed on the first passivation layer PAS1. The second via layer VIA2 may include a same material as the first via layer VIA1 or include a suitable material, for example, among the materials constituting the first via layer VIA1. For example, the second via layer VIA2 may be an organic insulating layer including an organic material.

In an embodiment, the second passivation layer PAS2 may be entirely provided and/or formed on the second via layer VIA2. In an embodiment, the second passivation layer PAS2 may include a same material as the first passivation layer PAS1. The second passivation layer PAS2 may be an inorganic insulating layer including an inorganic material.

In an embodiment, the third via layer VIA3 may be entirely provided and/or formed on the second passivation layer PAS2. In an embodiment, the third via layer VIA3 may include a same material as the first via layer PAS1. For example, the third via layer VIA3 may be an organic insulating layer including an organic material.

The pixel circuit layer PCL may include at least one conductive layer disposed between the above-described insulating layers. For example, the pixel circuit layer PCL may include a first conductive layer disposed between the substrate SUB and the buffer layer BFL, a second conductive layer disposed between the first gate insulating layer GI1 and the second gate insulating layer GI2, a third conductive layer disposed between the interlayer insulating layer ILD and the first via layer VIA1, a fourth conductive layer disposed between the first passivation layer PAS1 and the second via layer VIA2, and a fifth conductive layer disposed between the second passivation layer PAS2 and the third via layer VIA3.

In an embodiment, the first conductive layer may be formed as a single layer including any selected from the group consisting of copper, molybdenum, tungsten, neodymium, titanium, aluminum, silver, and any alloy thereof or a mixture thereof. In another embodiment, the first conductive layer may be formed as a double- or multi-layer structure including any of molybdenum, titanium, copper, aluminum, or silver, which is a low-resistance material so as to decrease wiring resistance. Each of the second to fifth conductive layers may include a same material as the first conductive layer or include at least one suitable material, for example, among the materials constituting the first conductive layer. However, the present disclosure is not limited thereto.

The pixel circuit layer PCL may include a pixel circuit PXC, and a plurality of electrodes and a plurality of lines, which are electrically connected to the pixel circuit PXC. For example, the pixel circuit layer PCL may include a bottom metal pattern BML, the transistor T, a connection electrode CCE, a second power line PL2, a first conductive pattern CP1, a second conductive pattern CP2, and a bridge pattern BRP, but the present disclosure is not limited thereto.

The bottom metal pattern BML may block light introduced to the pixel circuit PXC from the second surface SF2 of the substrate SUB. The bottom metal pattern BML may be the first conductive layer disposed between the substrate SUB and the buffer layer BFL. In some embodiments, the bottom metal pattern BML may be electrically connected to the transistor T. The driving range of a voltage (e.g., a predetermined voltage) supplied to a gate electrode GE of the transistor T may be widened. In a case in which the bottom metal pattern BML is electrically connected to the transistor T, a channel region of the transistor T may be stabilized. As the bottom metal pattern BML is electrically connected to the transistor T, floating of the bottom metal pattern BML may be prevented or substantially prevented.

The transistor T may include a semiconductor pattern and the gate electrode GE overlapping with one region of the semiconductor pattern. The transistor T may be, for example, the first transistor T1 described with reference to FIG. 3.

The semiconductor pattern may be disposed on the buffer layer BFL. The semiconductor pattern may include the channel region CHA, a first terminal TE1, and a second terminal TE2. In an embodiment, the first terminal TE1 and the second terminal TE2 may become conductors by annealing the semiconductor pattern (or doping a high-concentration impurity). For example, the semiconductor pattern may include polycrystalline silicon, single crystalline silicon, low temperature polycrystalline silicon, amorphous silicon, or an oxide semiconductor. In another example, the semiconductor pattern may include first and second active layers disposed in different layers. The first active layer may include polycrystalline silicon, single crystalline silicon, low temperature polycrystalline silicon, or amorphous silicon, and the second active layer may include an oxide semiconductor.

The gate electrode GE may be disposed on the first gate insulating layer GI1. The gate electrode GE may be the second conductive layer disposed between the first gate insulating layer GI1 and the second gate insulating layer GI2. The gate electrode GE may overlap with the channel region CHA of the semiconductor pattern. The first gate insulating layer GI1 disposed between the semiconductor pattern and the gate electrode GE may insulate the channel region CHA of the semiconductor pattern and the gate electrode GE from each other.

The second conductive layer including the gate electrode GE may be configured as a single layer or a multi-layer. The second gate insulating layer GI2 may be disposed over the above-described second conductive layer.

The interlayer insulating layer ILD may be disposed on the second gate insulating layer GI2.

The connection electrode CCE may be disposed on the interlayer insulating layer ILD. The connection electrode CCE may be the third conductive layer located between the interlayer insulating layer ILD and the first via layer VIA1. The connection electrode CCE may be connected to the second terminal TE2 of the transistor T while penetrating a contact hole of each of the interlayer insulating layer ILD, the second gate insulating layer GI2, and the first gate insulating layer GI1.

The second power line PL2 may be disposed on the interlayer insulating layer ILD. The second power line PL2 may be disposed on the interlayer insulating layer ILD to be spaced apart from the connection electrode CCE, and be configured as the third conductive layer.

The third conductive layer including the connection electrode CCE and the second power line PL2 may be configured as a single layer or a multi-layer.

The first via layer VIA1 may be disposed over the third conductive layer. The first via layer VIA1 may planarize a top end of the third conductive layer.

The first passivation layer PAS1 may be disposed on the first via layer VIA1.

The first conductive pattern CP1 and the second conductive pattern CP2 may be disposed on the first passivation layer PAS1. The first conductive pattern CP1 and the second conductive pattern CP2 may be the fourth conductive layer located between the first passivation layer PAS1 and the second via layer VIA2.

The first conductive pattern CP may be electrically insulated from a second electrode EL2, a fourth electrode EL4, and a common line COL except a case in which repairing is performed as the light emitting element LD is connected in a reverse direction to a first electrode EL1 and the second electrode EL2. The second conductive pattern CP2 may be electrically connected to the first electrode EL1 and a third electrode EL3 except a case in which repairing is performed as the light emitting element LD is connected in a reverse direction to the first and second electrodes EL1 and EL2.

The fourth conductive layer including the first conductive pattern CP1 and the second conductive pattern CP2 may be configured as a single layer or a multi-layer.

The second via layer VIA2 may be disposed over the fourth conductive layer. The second via layer VIA2 may planarize a top end of the fourth conductive layer.

The second passivation layer PAS2 may be disposed on the second via layer VIA2.

The bridge pattern BRP may be disposed on the second passivation layer PAS2. The bridge pattern BRP may be the fifth conductive layer located between the second passivation layer PAS2 and the third via layer VIA3. The bridge pattern BRP may be electrically connected to the connection electrode CCE while penetrating a contact hole of each of the second passivation layer PAS2, the second via layer VIA2, the first passivation layer PAS1, and the first via layer VIA1. The bridge pattern BRP may be electrically connected to the transistor T through the connection electrode CCE. The fifth conductive layer including the bridge pattern BRP may be configured as a single layer or a multi-layer.

In addition, the first power line PL1 to which the voltage of the first driving power source VDD is applied may be disposed in the pixel circuit layer PCL. In an embodiment, the first power line PL1 may be located in a same layer as the second power line PL2, but the present disclosure is not limited thereto.

In the above-described embodiment, it has been described that the first conductive pattern CP1 and the second conductive pattern CP2 are disposed on the first passivation layer PAS1. However, the present disclosure is not limited thereto. The first conductive pattern CP1 and the second conductive pattern CP2 may be disposed on at least one insulating layer among the insulating layers included in the pixel circuit layer PCL. The first conductive pattern CP1 and the second conductive pattern CP2 may be disposed in a same layer, but the present disclosure is not limited thereto. In some embodiments, the first conductive pattern CP1 and the second conductive pattern CP2 may be disposed in different layers.

In an embodiment, the third via layer VIA3 may be entirely disposed over the above-described fifth conductive layer. The third via layer VIA3 may planarize a top end of the fifth conductive layer. In an embodiment, the third via layer VIA3 may include a first contact hole CH1 exposing a portion of the bridge pattern BRP.

A sixth conductive layer may be disposed on the pixel circuit layer PCL having the above-described configuration. The sixth conductive layer may include the first electrode EL1, the second electrode EL2, the third electrode EL3, the fourth electrode EL4, and the common line COL, which are disposed on the third via layer VIA3 of the pixel circuit layer PCL. The sixth conductive layer may include a suitable material, for example, among the materials described as the material constituting the first conductive layer, and be configured as a single layer or a multi-layer.

The first electrode EL1, the second electrode EL2, the third electrode EL3, and the fourth electrode EL4 may be disposed on the third via layer VIA3 to be spaced apart from each other. In an embodiment, the first electrode EL1 and the third electrode EL3 may be integrally formed to be electrically connected to each other. In an embodiment, the second electrode EL2 and the fourth electrode EL4 may be integrally formed to be electrically connected to each other. The second electrode EL2 and the fourth electrode EL4 may branch off from the common line COL. In an embodiment, the second electrode EL2, the fourth electrode EL4, and the common electrode COL may be integrally formed to be electrically connected to each other.

In an embodiment, the first electrode EL1 may include four first sub-electrodes, and the second electrode EL2 may include four second sub-electrodes. For example, the first electrode EL1 may include a (1-1)th sub-electrode SUE1_1, a (1-2)th sub-electrode SUE1_2, a (1-3)th sub-electrode SUE1_3, and a (1-4)th sub-electrode SUE1_4. The second electrode EL2 may include a (2-1)th sub-electrode SUE2_1, a (2-2)th sub-electrode SUE2_2, a (2-3)th sub-electrode SUE2_3, and a (2-4)th sub-electrode SUE2_4.

The (1-3)th sub-electrode SUE1_3 of the first electrode EL1 may be electrically connected to the first conductive pattern CP1 through a first contact portion CNT1 penetrating the third via layer VIA3, the second passivation layer PAS2, and the second via layer VIA2. The (2-2)th sub-electrode SUE2_2 of the second electrode EL2 may be electrically connected to the second conductive pattern CP2 through a second contact portion CNT2 penetrating the third via layer VIA3, the second passivation layer PAS2, and the second via layer VIA2.

The third electrode EL3 may be electrically connected to a partial component, e.g., the transistor T of the pixel circuit layer PCL through the first contact hole CH1 of the third via layer VIA3.

The common line COL may be electrically connected to the second power line PL2 through a second contact hole CH2 penetrating the third via layer VIA3, the second passivation layer PAS2, the second via layer VIA2, the first passivation layer PAS1, and the first via layer VIA1.

In the above-described embodiment, the first electrode EL1 (or the first sub-electrodes) may be an anode electrode electrically connected to the first end portion EP1 of the light emitting element LD, and the second electrode EL2 (or the second sub-electrodes) may be a cathode electrode electrically connected to the second end portion EP2 of the light emitting element LD. In some embodiments, each of the first electrode EL1 and the second electrode EL2 may be a bonding electrode bonded to the light emitting element LD. Each of the first electrode EL1 and the second electrode EL2 may be bonded to a bonding electrode of the light emitting element LD, thereby electrically connecting the light emitting element LD and the pixel circuit PXC to each other.

In an embodiment, the first electrode EL1, the second electrode EL2, the third electrode EL3, the fourth electrode EL4, and the common line COL may be formed through a same process to be located in a same layer, and include a same material.

The sixth conductive layer including the first electrode EL1, the second electrode EL2, the third electrode EL3, the fourth electrode EL4, and the common line COL may be located on the third via layer VIA3, and may be formed of a conductive material having a reflectivity to allow light emitted from the light emitting element LD to advance in an image display direction (or front direction) of the display device DD. The conductive material, in an embodiment, may include an opaque metal suitable for reflecting light emitted from the light emitting element LD in the image display direction (or a desired direction) of the display device DD. The opaque material may include any of metals, such as silver, magnesium, aluminum, platinum, palladium, gold, nickel, neodymium, iridium, chromium, titanium, and alloys thereof. In some embodiments, the sixth conductive layer may include a transparent conductive material (or substance). The transparent conductive material (or substance) may include any of a conductive oxide, such as indium tin oxide (ITO), indium zinc oxide (IZO), zinc oxide (ZnO), indium gallium zinc oxide (IGZO), or indium tin zinc oxide (ITZO), a conductive polymer such as poly(3,4-ethylenedioxythiophene (PEDOT), and the like. In a case in which the sixth conductive layer includes a transparent conductive material (or substance), a separate conductive layer may be added, which is formed of an opaque metal for reflecting light emitted from the light emitting element LD in the image display direction of the display device DD. However, a material of the sixth conductive layer is not limited to the above-described materials.

The sixth conductive layer may be formed as a single layer and/or a multi-layer, but the present disclosure is not limited thereto. In some embodiments, the sixth conductive layer may be provided and/or formed as a multi-layer in which at least two materials among metals, alloys, conductive oxide, and conductive polymers are stacked. The sixth conductive layer may be formed as a multi-layer including at least two layers.

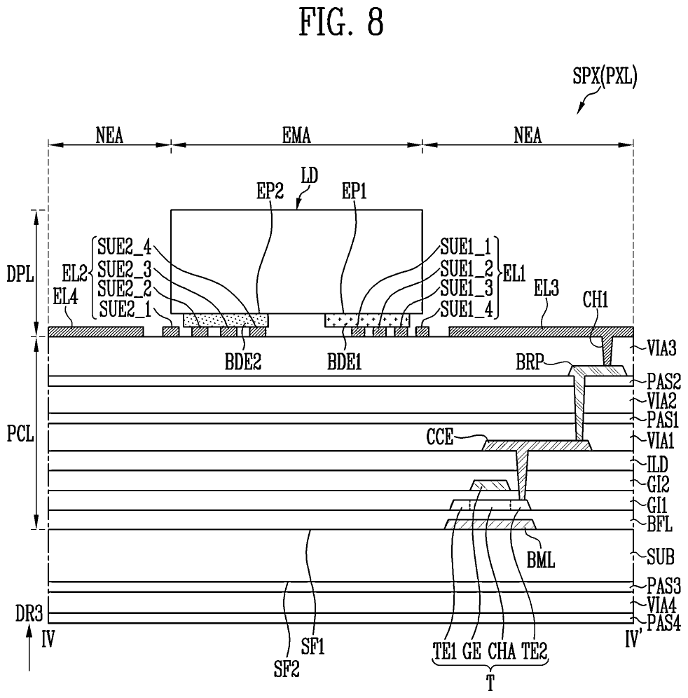

The sub-pixel SPX (or the pixel PXL) including the light emitting element LD bonded to the first and second electrodes EL1 and EL2 will be described in further detail with reference to FIGS. 7 to 9.

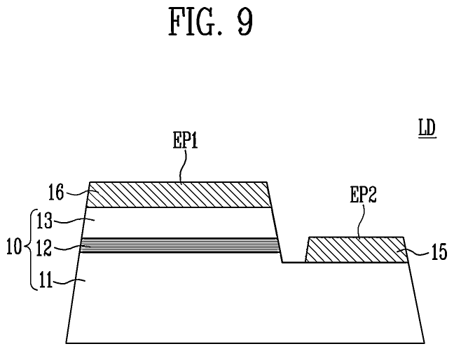

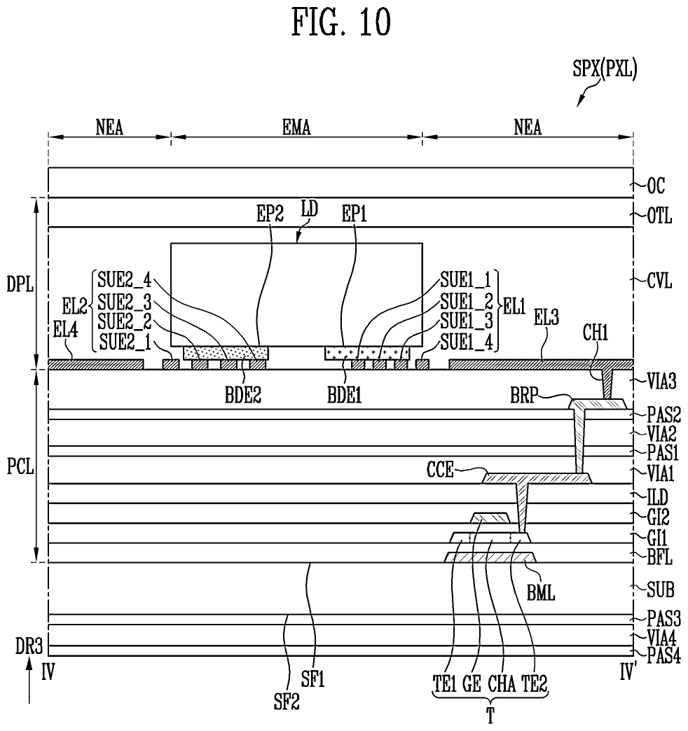

FIG. 7 is a schematic plan view illustrating a state in which a light emitting element LD is transferred in the sub-pixel SPX shown in FIG. 4. FIG. 8 is a schematic cross-sectional view taken along line IV-IV′ shown in FIG. 7. FIG. 9 is a schematic cross-sectional view illustrating the light emitting element LD shown in FIG. 8.

In relation to the embodiment shown in FIGS. 7 to 9, portions different from those of the above-described embodiment will be mainly described to avoid redundancy.

Referring to FIGS. 7 to 9, the sub-pixel SPX (or the pixel PXL) may include a substrate SUB, a pixel circuit layer PCL, and a display element layer DPL.

The pixel circuit layer PCL may include a transistor T, a first conductive pattern CP1, a second conductive pattern CP2, and the like.

The display element layer DPL may include first to fourth electrodes EL1 to EL4, a common line COL, and a light emitting element LD. The sub-pixel SPX may include an emission area EMA in which light is emitted from the light emitting element LD and a non-emission area NEA located at a periphery of the emission area EMA. The light is not emitted in the non-emission area NEA.

The first to fourth electrodes EL1 to EL4 may be disposed on a third via layer VIA3 of the pixel circuit layer PCL to be spaced apart from each other. The first electrode EL1 and the third electrode EL3 may be electrically connected to each other. The second electrode EL2, the fourth electrode EL4, and the common line COL may be electrically connected to each other. The first electrode EL1 may include (1-1)th to (1-4)th sub-electrodes SUE1_1 to SUE1_4, and the second electrode EL2 may include (2-1)th to (2-4)th sub-electrodes SUE2_1 to SUE2_4.

The common line COL may be provided in a form in which the common line COL surrounds the first to fourth electrodes EL1 to EL4 in a plan view, and be electrically connected to the second power line PL2 through a second contact hole CH2.

The light emitting element LD may be bonded to each of the first and second electrodes EL1 and EL2. The light emitting element LD may include a semiconductor structure 10, a first contact electrode 15, and a second contact electrode 16. In an embodiment, the semiconductor structure 10 may be formed by sequentially forming a first semiconductor layer 11, an active layer 12, and a second semiconductor layer 13, and then performing mesh etching, but the present disclosure is not limited thereto. The first contact electrode 15 and the second contact electrode 16 may be sequentially formed on the semiconductor structure 10, thereby forming the light emitting element LD in a package form. However, the present disclosure is not limited thereto.

Each of a length of the light emitting element LD in a longitudinal direction, a length of the light emitting element LD in a lateral direction, and a length of the light emitting element LD in a thickness direction may be a few to a few hundreds of μm.

In an embodiment, the light emitting element LD may be formed by being grown on a semiconductor substrate, such as a silicon wafer. The light emitting element LD may be transferred immediately on the first electrode EL1 and the second electrode EL of the display element layer DPL from the silicon wafer. In another embodiment, the light emitting element LD may be transferred on the first electrode EL1 and the second electrode EL of the display element layer DPL through an electrostatic process using an electrostatic head or a stamping process using, as a transfer substrate, a polymer material having elasticity, such as PDMS or silicon.

In an embodiment, the light emitting element LD may include a first end portion EP1 in contact with the first electrode EL1 (or first sub-electrodes) and a second end portion EP2 in contact with the second electrode EL2 (or second sub-electrodes). The light emitting element LD may include a light emitting element (or light emitting diode) having a horizontal-type structure, which the first end portion EP1 and the second end portion EP2 are located on the same plane. The second contact electrode 16 electrically connected to the second semiconductor layer 13 may be located at the first end portion EP1, and the first contact electrode 15 electrically connected to the first semiconductor layer 11 may be located at the second end portion EP2.

In an embodiment, in a plan view, the light emitting element LD may be disposed only on the first electrode EL1 and the second electrode EL2, which are located between the third electrode EL3 and the fourth electrode EL4. The first end portion EP1 of the light emitting element LD may be disposed on the first electrode EL1 (or first sub-electrodes) to be electrically connected to the first electrode EL1, and the second end portion EP2 of the light emitting element LD may be disposed on the second electrode EL2 (or second sub-electrodes) to be electrically connected to the second electrode EL2. The light emitting element LD is not disposed on the third electrode EL3 and the fourth electrode EL4, and may not overlap with the third electrode EL3 and the fourth electrode EL4.

The semiconductor structure 10 may emit light as electrons and holes are recombined according to a current flowing between the first contact electrode 15 and the second contact electrode 16. The semiconductor structure 10 may include the first semiconductor layer 11, the active layer 12, and the second semiconductor layer 13.

The first semiconductor layer 11 may include, for example, at least one n-type semiconductor layer. For example, the first semiconductor layer 11 may include at least one semiconductor material among InAlGaN, GaN, AlGaN, InGaN, AlN, and InN, and be an n-type semiconductor layer doped with a first conductive dopant (or n-type dopant), such as Si, Ge or Sn. However, a material constituting the first semiconductor layer 11 is not limited thereto. In addition, the first semiconductor layer 11 may be configured with various materials. In an embodiment, the first semiconductor layer 11 may include a gallium nitride (GaN) semiconductor material doped with a first conductive dopant (or n-type dopant).

The active layer 12 (or light emitting layer) may be disposed on a portion of a surface of the first semiconductor layer 11. The active layer 12 may include a material having a single or multiple quantum well structure. In a case in which the active layer 12 may include a material having the multiple quantum well structure, the active layer 12 may have a structure in which a plurality of well layers and a plurality of barrier layers are alternately stacked. The well layer may be formed of InGaN, and the barrier layer may be formed of GaN or AlGaN. However, the present disclosure is not limited thereto. In another embodiment, the active layer 12 may have a structure in which a semiconductor material having a high band gap energy and a semiconductor material having a low band gap energy are alternately stacked, and include Group III to Group V semiconductor materials according to a wavelength band of emitted light. The active layer 12 may include a first surface in contact with the first semiconductor layer 11 and a second surface in contact with the second semiconductor layer 13.

The second semiconductor layer 13 may be disposed on a surface of the active layer 12, and provide holes to the active layer 12. The second semiconductor layer 13 may include a semiconductor layer having a type different from the type of the first semiconductor layer 11. For example, the second semiconductor layer 13 may include at least one p-type semiconductor layer. For example, the second semiconductor layer 13 may include at least one semiconductor material among InAlGaN, GaN, AlGaN, InGaN, AlN, and InN, and include a p-type semiconductor layer doped with a second conductive dopant (or p-type dopant), such as Mg, Zn, Ca, Sr, or Ba. However, a material constituting the second semiconductor layer 13 is not limited thereto. In addition, the second semiconductor layer 13 may be configured with various materials. In an embodiment, the second semiconductor layer 13 may include a gallium nitride (GaN) semiconductor material doped with a second conductive dopant (or p-type dopant).

The first semiconductor layer 11, the active layer 12, and the second semiconductor layer 13, which are described above, may be provided in a structure in which the first semiconductor layer 11, the active layer 12, and the second semiconductor layer 13 are sequentially stacked on a semiconductor substrate. The semiconductor substrate may include a semiconductor material, such as a sapphire substrate or a silicon substrate. The semiconductor substrate may be used as a substrate for growth, which is used to grow each of the first semiconductor layer 11, the active layer 12, and the second semiconductor layer 13, and then be separated from the first semiconductor layer 11 through a substrate separation process. The substrate separation process may be laser lift off (LLO), chemical lift off (CLO), or the like. Accordingly, as the semiconductor substrate for growth is removed from the semiconductor structure 10, the semiconductor structure 10 may have a thin thickness. The above-described semiconductor structure 10 may have a small size of micro scale (or micrometer), for example, but the present disclosure is not limited thereto.

The first contact electrode 15 may be provided and/or formed on the semiconductor structure 10. For example, the first contact electrode 15 may be provided and/or formed on the first semiconductor layer 11 to be electrically separated from (or electrically disconnected to) the active layer 12 and the second semiconductor layer 13. The first contact electrode 15 may be in ohmic contact with the first semiconductor layer 11. In an embodiment, the first contact electrode 15 may be located at the second end portion EP2 (or n-type end portion) of the light emitting element LD, and be in contact with a second bonding electrode BDE2 for bonding.

The second contact electrode 16 may be provided and/or formed on the semiconductor structure 10. For example, the second contact electrode 16 may be provided and/or formed on the second semiconductor layer 13. The second contact electrode 16 may be in ohmic contact with the second semiconductor layer 13. In an embodiment, the second contact electrode 16 may be located at the first end portion (or p-type end portion) of the light emitting element LD, and be in contact with a first bonding electrode BDE1 for bonding.

The first and second contact electrodes 15 and 16 may include a conductive material. For example, the first and second contact electrodes 15 and 16 may include an opaque metal using any or a mixture of chromium, titanium, aluminum, gold, nickel, and any oxide or alloy thereof, but the present disclosure is not limited thereto. In some embodiments, the first and second contact electrodes 15 and 16 may include a transparent conductive oxide, such as indium tin oxide (ITO), indium zinc oxide (IZO), zinc oxide (ZnOₓ), indium gallium zinc oxide (IGZO), or indium tin zinc oxide (ITZO). In some embodiments, the first and second contact electrodes 15 and 16 may be solder bumps.

In some embodiments, the light emitting element LD may further include an insulative film around (e.g., surrounding) an outer circumferential surface of the semiconductor structure 10.

The light emitting element LD may be bonded to each of the first and second electrodes EL1 and EL2 through a bonding electrode. For example, the first end portion EP1 (or p-type end portion) of the light emitting element LD may be bonded to the first electrode EL1 (or first sub-electrodes) through the first bonding electrode BDE1, and the second end portion EP2 (or n-type end portion) of the light emitting element LD may be bonded to the second electrode EL2 (or second sub-electrodes) through the second bonding electrode BDE2. In an embodiment, each of the first and second bonding electrodes BDE1 and BDE2 may be selected from gold, tin, and the like, which have an excellent coupling strength (or adhesive strength), to facilitate generation and growth of an intermetallic compound. However, the present disclosure is not limited thereto. In some embodiments, the first bonding electrode BDE1 and the second bonding electrode BDE2 may be omitted.

The light emitting element LD may be disposed on the third via layer VIA3 such that the first end portion EP1 of the light emitting element LD (or the first bonding electrode BDE1) is located on the first electrode EL1 and the second end portion EP2 of the light emitting element LD (or the second bonding electrode BDE2) is located on the second electrode EL2. After the light emitting element LD transferred to a transfer base by a transportation device is moved to the top of the first electrode EL1 and the second electrode EL2, the light emitting element LD may be re-transferred on the first and second electrodes EL1 and EL2.

In a case in which the first end portion EP1 (or p-type end portion) of the light emitting element LD is electrically connected to the first electrode EL1 and the second end portion EP2 (or n-type end portion) of the light emitting element LD is electrically connected to the second electrode EL2, the light emitting element LD may be connected in a forward direction between the first electrode EL1 and the second electrode EL2. In a case in which a driving current flows from the first power line PL1 to the second power line PL2 by means of the transistor T, the driving current may flow into the third electrode EL3 and the first electrode EL1 electrically connected to the third electrode EL3 through a first contact hole CH1. Accordingly, the light emitting element LD may emit light with a luminance corresponding to the driving current.

In an embodiment, as the first electrode EL1 electrically connected to the first end portion EP1 of the light emitting element LD (or the first bonding electrode BDE1) while being in contact with the first end portion EP1 of the light emitting element LD includes a plurality of first sub-electrodes, and the second electrode EL2 electrically connected to the second end portion EP2 of the light emitting element LD (or the second bonding electrode BDE2) while being in contact with the second end portion EP2 of the light emitting element LD includes a plurality of second sub-electrodes, a current path through which a current flows in a direction from the first electrode EL1 to the second electrode EL2 may be provided in plural. Accordingly, although the first end portion EP1 of the light emitting element LD is in contact with at least some of the first sub-electrodes and the second end portion EP2 of the light emitting element LD is in contact with at least some of the second sub-electrodes, each end portion of the light emitting element LD and a corresponding electrode can be stably electrically connected to each other. Thus, the reliability of the sub-pixel SPX (or the display device DD) can be improved.

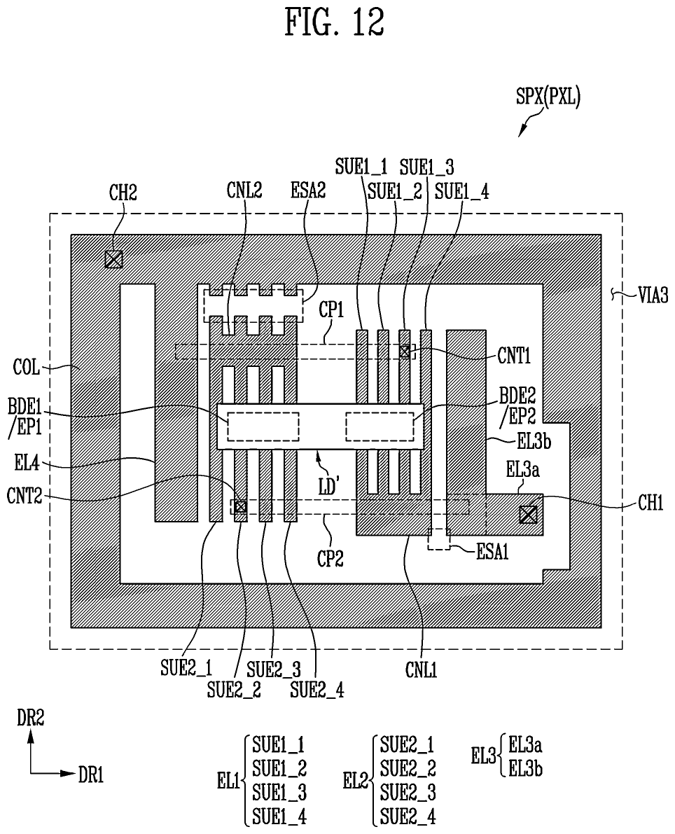

After the light emitting element LD is transferred on the first and second electrodes EL1 and EL2, a lighting test on the light emitting element LD may be performed. In a case in which any defect does not exist in the light emitting element LD, the sub-pixel SPX (or the display device DD) may be completed. However, in a case in which the sub-pixel SPX is blackened as the light emitting element LD does not emit light in the above-described lighting test, a repairing process may be performed according to a kind of a defect of the light emitting element LD. For example, in a case in which a dark spot defect occurs in the sub-pixel SPX as the light emitting element LD is connected in a reverse direction between the first and second electrodes EL1 and EL2 due to a condition (e.g., alignment accuracy) of equipment, an atmosphere of environment in an apparatus, or the like in a process of transferring the light emitting element LD on the first and second electrodes EL1 and EL2, repairing may be performed to allow a current to flow through the light emitting element LD connected in the reverse direction by changing a current direction of the sub-pixel SPX to the opposite direction of the current direction. The repairing of the light emitting element connected in the reverse direction will be described in further detail later with reference to FIGS. 11 to 15B.

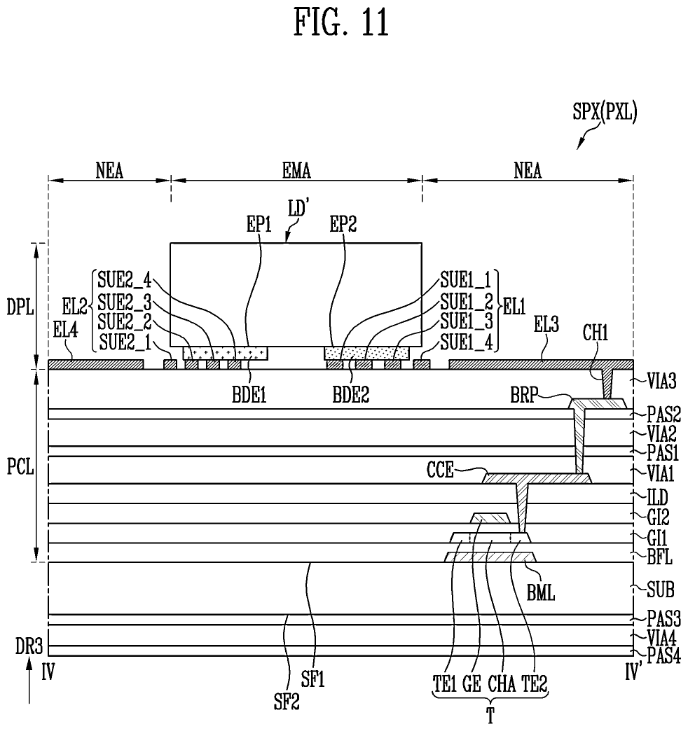

FIG. 10 illustrates a sub-pixel SPX in accordance with an embodiment of the present disclosure, and is a schematic cross-sectional view corresponding to the line IV-IV′ shown in FIG. 7.

In relation to the embodiment shown in FIG. 10, portions different from those of the above-described embodiment will be mainly described to avoid redundancy.

Referring to FIGS. 7 and 10, the sub-pixel SPX may include a substrate SUB, a pixel circuit layer PCL, a display element layer DPL, and an overcoat layer OC.

The pixel circuit layer PCL may be located on a first surface SF1 of the substrate SUB, and include a transistor T, a first conductive pattern CP1, and a second conductive pattern CP2.

The display element layer DPL may be located on the pixel circuit layer PCL, and include first to fourth electrodes EL1 to EL4, a common line COL, a light emitting element LD, a cover layer CVL, and an optical layer OTL.

The cover layer CVL may be disposed over a sixth conductive layer including the first to fourth electrodes EL1 to EL4 and the common line COL and the light emitting element LD, to cover the sixth conductive layer and the light emitting element LD. The cover layer CVL may be an encapsulation substrate or an encapsulation film formed as a multi-layer. The cover layer CVL may prevent or substantially prevent external oxygen, external moisture, and the like from being introduced to the light emitting element LD and the pixel circuit layer PCL. In some embodiments, the cover layer CVL may be a planarization layer for reducing a step difference occurring due to components disposed thereunder.

The optical layer OTL may be provided on the cover layer CVL.

The optical layer OTL may convert light emitted from the light emitting element LD into light having excellent color reproducibility and then emit the converted light, thereby improving the light emission efficiency of each sub-pixel SPX (or each pixel PXL). The optical layer OTL may include a color filter layer including a color filter and a light blocking pattern. In some embodiments, the optical layer OTL may also include a color conversion layer including color conversion particles for converting light emitted from the light emitting element LD into light of a specific light (or light having excellent color reproducibility).

The overcoat layer OC may be disposed over the optical layer OTL. The overcoat layer OC may cover a lower member including the optical layer OTL. The overcoat layer OC may protect the above-described lower member from foreign matter, such as dust.

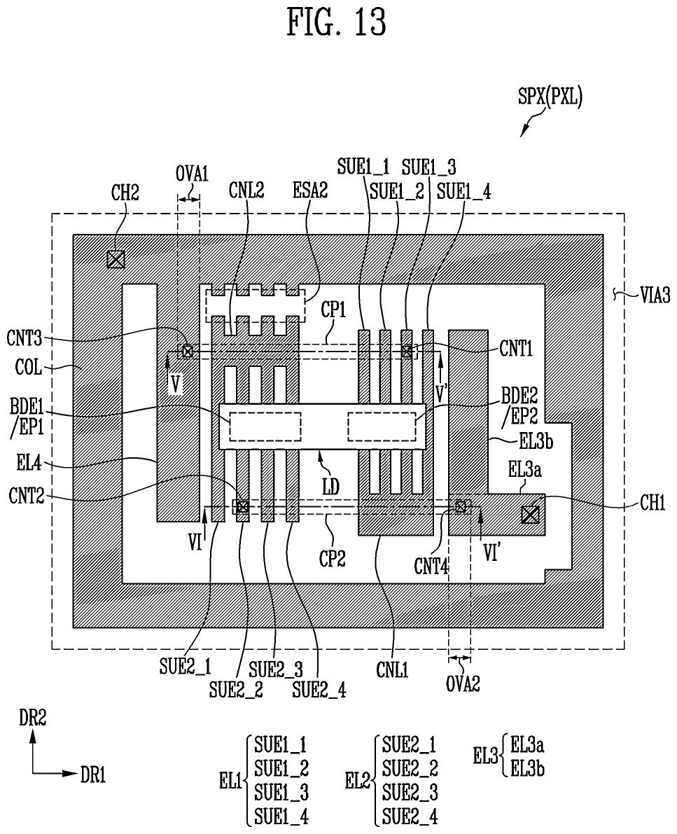

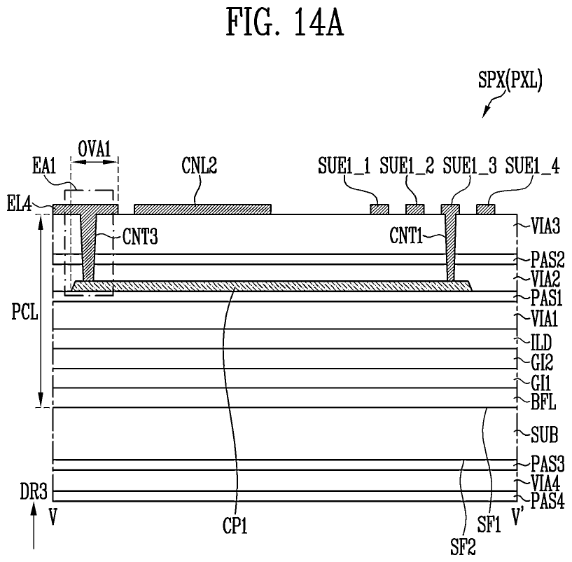

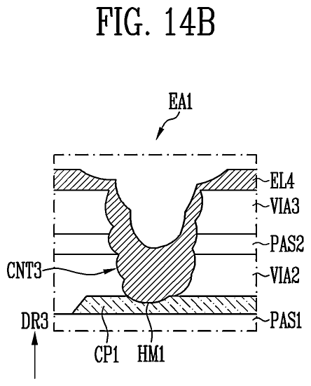

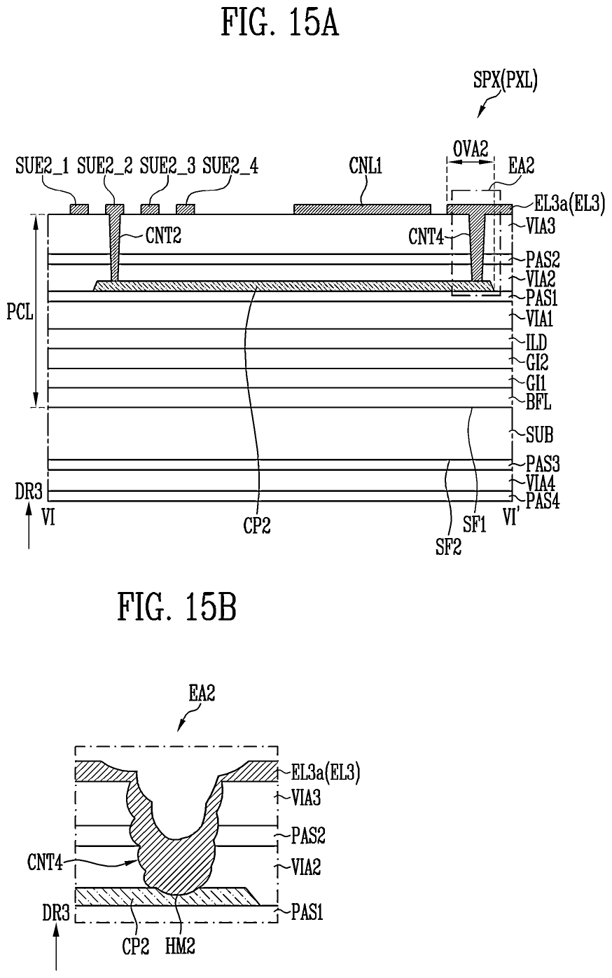

FIG. 11 illustrates a sub-pixel SPX including a defective light emitting element LD′, and is a schematic cross-sectional view corresponding to the line IV-IV′ shown in FIG. 7. FIGS. 12 and 13 are schematic plan views illustrating a method of repairing the defective light emitting element LD′ shown in FIG. 11. FIG. 14A is a schematic cross-sectional view taken along the line V-V′ shown in FIG. 13; and FIG. 14B is a schematic enlarged cross-sectional view of a region “EA1” shown in FIG. 14A. FIG. 15A is a schematic cross-sectional view taken along the line VI-VI′ shown in FIG. 13; and FIG. 15B is a schematic enlarged cross-sectional view of a region “EA2” shown in FIG. 15A.

Referring to FIGS. 7 and 11 to 15B, the sub-pixel SPX (or a pixel PXL) may include a defective light emitting element LD′ connected in a reverse direction between the first electrode EL1 and the second electrode EL2.

The defective light emitting element LD′ may be a reverse light emitting element of which alignment direction is defective, as in the process of transferring the light emitting LD on the first electrode EL1 and the second electrode EL2, which is described with reference to FIGS. 7 to 9, the first end portion EP1 of the light emitting element LD (or the first bonding electrode BDE1) is electrically connected to the second electrode EL2 while being in contact with the second electrode EL2 and the second end portion EP2 of the light emitting element LD (or the second bonding electrode BDE2) is electrically connected to the first electrode EL1 while being in contact with the first electrode EL1. The defective light emitting element LD′ is connected in the opposite direction of the alignment direction of the light emitting element LD between the first electrode EL1 and the second electrode EL2, and maintains an inactive state even in a case in which a certain driving voltage (e.g., a predetermined driving voltage) (e.g., a driving voltage in the forward direction) is applied between the first and second electrodes EL1 and EL2, such that any current does not substantially flow.

The sub-pixel SPX including the above-described defective light emitting element LD′ may be blackened, and a repairing process for solving such a dark spot defect may be performed. For example, in the repairing process, each of an electrical connection between the first electrode EL1 and the third electrode EL3 and an electrical connection between the second electrode EL2 and the fourth electrode EL4 may be cut off, using a laser, for example, and a corresponding electrode and a corresponding conductive pattern may be electrically connected to each other by performing a bonding process using the laser.

As shown in FIG. 12, a portion of the first connection line CNL1 may be removed, using the laser, in a first electrode separation area ESA1 between the first electrode EL1 (or first sub-electrodes) and the third electrode EL3, thereby electrically separating the first electrode EL1 and the third electrode EL3 from each other. In addition, a portion of the second electrode EL2 (or second sub-electrodes) may be removed, using the laser, in a second electrode separation area ESA2 between the second electrode EL1 (or second sub-electrodes) and the common line COL, thereby electrically separating the second electrode EL2 and the common line COL from each other. Accordingly, the second electrode EL2 and the fourth electrode EL4 may be electrically disconnected from each other. The first electrode EL1 (or first sub-electrodes) electrically disconnected from the third electrode EL3 and the second electrode EL2 (or second sub-electrodes) electrically disconnected from the fourth electrode EL4 may be floated.

The first electrode EL1 electrically disconnected from the third electrode EL3 may be electrically connected to a first end (e.g., a “right end portion” in a plan view) of the first conductive pattern CP1 through the first contact portion CNT1. The second electrode EL2 electrically disconnected from the common line COL may be electrically connected to a first end (e.g., a “left end portion” in a plan view) of the second conductive pattern CP2 through the second contact portion CNT2.

After the electrical connection between the electrodes is cut off, using the laser, as described above, a process of electrically connecting a corresponding conductive pattern and a corresponding electrode to each other through a laser bonding process may be performed. For example, as shown in FIG. 13, the third electrode EL3 and the second electrode EL2 may be electrically connected to each other through the second conductive pattern CP2, and the fourth electrode EL4 and the first electrode EL1 may be electrically connected to each other through the first conductive pattern CP1.

The laser bonding process performed after the first electrode EL1 and the third electrode EL3 are electrically disconnected from each other may mean a process of forming a third contact portion CNT3 exposing a second end (e.g., a “left end portion” on a plane) of the first conductive pattern CP1 by intensively irradiating laser onto the top of the fourth electrode EL4 overlapping with the second end of the first conductive pattern CP1 and then removing portions of insulating layers located between the second end of the first conductive pattern CP1 and the fourth electrode EL4, such that the second end of the first conductive pattern CP1 and the fourth electrode EL4 are electrically connected to each other. In some embodiments, in a case in which the first conductive pattern CP1 and the fourth electrode EL4 are formed of copper or gold, a laser bonding process using a laser having a wavelength of about 532 nm or less may be performed. In a case in which the first conductive pattern CP1 and the fourth electrode EL4 are formed of aluminum, a laser bonding process using a laser having a wavelength of about 750 nm to about 900 nm may be performed. In a plan view, the third contact portion CNT3 may be located in a first overlapping area OVA1 in which a second end of the first conductive pattern CP1 and the fourth electrode EL4 overlap with each other.

In a case in which the laser is irradiated on a top of the fourth electrode EL4 in the first overlapping area OVA1, the transmittance and/or absorptivity of a laser beam may vary according to a material characteristic of each of the third via layer VIA3, the second passivation layer PAS2, and the second via layer VIA2, which are located between the first conductive pattern CP1 and the fourth electrode EL4. Therefore, an etching degree of each of the third via layer VIA3, the second passivation layer PAS2, and the second via layer VIA2 may vary. Accordingly, the third contact portion CNT3 may have a non-uniform sidewall as shown in FIG. 14B. In addition, in some embodiments, a first groove portion HM1 may be formed at the second end of the first conductive pattern CP1, which is exposed by the third contact portion CNT3. The first groove portion HM1 may be formed as a portion of the first conductive pattern CP1 is melted in the opposite direction of the third direction DR3 from a surface (or upper surface) of the first conductive pattern CP1 by the laser irradiated in the laser bonding process.

The third contact portion CNT3 may be formed as portions of the insulating layers between the first conductive pattern CP1 and the fourth electrode EL4 are etched by the laser irradiated in the above-described laser bonding process, and the first conductive pattern CP1 and the fourth electrode EL4 may be electrically connected to each other as the first conductive pattern CP1 and the fourth electrode EL4 are fused by the laser while the second end of the first conductive pattern CP1 is exposed to the outside through the third contact portion CNT3.

The laser bonding process performed after the second electrode EL2 and the common line COL are electrically disconnected to each other may mean a process of forming a fourth contact portion CNT4 exposing a second end (e.g., a “right end portion” on a plane) of the second conductive patter CP2 by intensively irradiating a laser onto a top of the third electrode EL3 overlapping with the second end of the second conductive pattern CP2 and then removing portions of insulating layers located between the other end of the second conductive pattern CP2 and the third electrode EL3, such that the second end of the second conductive pattern CP2 and the third electrode EL3 are electrically connected to each other. In some embodiments, in a case in which the second conductive pattern CP2 and the third electrode EL3 are formed of copper or gold, a laser bonding process using a laser having a wavelength of about 532 nm or less may be performed. In a case in which the second conductive pattern CP2 and the third electrode EL3 are formed of aluminum, a laser bonding process using a laser having a wavelength of about 750 nm to about 900 nm may be performed. In a plan view, the fourth contact portion CNT4 may be located in a second overlapping area OVA2 in which the second end of the second conductive pattern CP2 and the third electrode EL3 overlap with each other.

In a case in which the laser is irradiated on a top of the third electrode EL3 (or the first portion EL3a) in the second overlapping area OVA2, the transmittance and/or absorptivity of a laser beam may vary according to a material characteristic of each of the third via layer VIA3, the second passivation layer PAS2, and the second via layer VIA2, which are located between the second conductive pattern CP2 and the third electrode EL3. Therefore, an etching degree of each of the third via layer VIA3, the second passivation layer PAS2, and the second via layer VIA2 may vary. Accordingly, the fourth contact portion CNT4 may have a non-uniform sidewall as shown in FIG. 15B. In addition, in some embodiments, a second groove portion HM2 may be formed at the second end of the second conductive pattern CP2, which is exposed by the fourth contact portion CNT4. The second groove portion HM2 may be formed as a portion of the second conductive pattern CP2 is melted in the opposite direction of the third direction DR3 from a surface (or upper surface) of the second conductive pattern CP2 by the laser irradiated in the laser bonding process.

The fourth contact portion CNT4 may be formed as portions of the insulating layers between the second conductive pattern CP2 and the third electrode EL3 are etched by the laser irradiated in the above-described laser bonding process, and the second conductive pattern CP2 and the third electrode EL3 may be electrically connected to each other as the second conductive pattern CP2 and the third electrode EL3 are fused by the laser while the second end of the second conductive pattern CP2 is exposed to the outside through the fourth contact portion CNT4.

After the above-described laser bonding process is performed, the third electrode EL3 may be electrically connected to the second end of the second conductive pattern CP2 through the fourth contact portion CNT4, and the fourth electrode EL4 may be electrically connected to the second end of the first conductive pattern CP1 through the third contact portion CNT3.

The first electrode EL1 (or the (1-3)th sub-electrode SUE1_3) electrically connected to the first end of the first conductive pattern CP1 through the first contact portion CNT1 may be electrically connected to the fourth electrode EL4 through the first conductive pattern CP1. The second electrode EL2 (or the (2-2)th sub-electrode SUE2_2) electrically connected to the first end of the second conductive pattern CP2 through the second contact portion CNT2 may be electrically connected to the third electrode EL3 through the second conductive pattern CP2. Therefore, the first electrode EL1 may be electrically connected to the second power line PL2 through the first conductive pattern CP1 and the fourth electrode EL4, and the second electrode EL2 may be electrically connected to the transistor T of the pixel circuit PXC through the second conductive pattern CP2 and the third electrode EL3. Accordingly, a current may flow between the second electrode EL2 and the first electrode EL1. The current may flow in a direction from the second electrode EL2 to the first electrode EL1 via the light emitting element LD. The second electrode EL2 may become an anode electrode, and the first electrode EL1 may become a cathode electrode. As such, the direction of current flowing from the first electrode EL1 to the second electrode EL2 is changed to the direction from the second electrode EL2 to the first electrode EL1 by repairing the sub-pixel SPX in which a dark spot defect occurs, such that the defective light emitting element LD′ may be connected in the forward direction between the second electrode EL2 and the first electrode EL1. Accordingly, the sub-pixel SPX in which the dark spot defect occurs is repaired by allowing the defective light emitting element LD′ to be driven as the light emitting element LD as an effective light source, such that the reliability of the display device DD can be improved.

In general, in a case in which a dark spot defect occurred in a sub-pixel SPX due to a defective light emitting element LD′ connected in the reverse direction between the first and second electrodes EL1 and EL2, a repairing process of removing the defective light emitting element LD′, using a laser, and then re-transferring another light emitting element LD on the first and second electrodes EL1 and EL2 was performed. A process of removing the defective light emitting element LD′ and a process of re-transferring the another light emitting element LD on the first and second electrodes EL1 and EL2 are added. Therefore, the manufacturing efficiency of the display device DD may be deteriorated, and the manufacturing cost of the display device DD may be increased due to unnecessary waste of the light emitting element LD.

In the above-described embodiment, in a case in which a light emitting element LD is determined as a defective light emitting element LD′ connected in the reverse direction between the first and second electrodes EL1 and EL2 after the light emitting element LD is transferred on the first and second electrodes EL1 and EL2, electrical connection between the first electrode EL1 and the third electrode EL3 and electrical connection between the second electrode EL2 and the fourth electrode EL4 are cut off, and a direction of current flowing from the first electrode EL1 to the second electrode EL2 is changed to a direction from the second electrode EL2 to the first electrode EL1, using the first and second conductive patterns CP1 and CP2 disposed under the first to fourth electrodes EL1 to EL4. Thus, the sub-pixel in which a dark spot defect occurs can be readily repaired by allowing the defective light emitting element LD′ to be driven as a light emitting element LD as an effective light source. Accordingly, in the above-described embodiment, manufacturing efficiency of the display device DD can be improved, and light emitting elements LD can be prevented or substantially prevented from being unnecessarily wasted, thereby reducing the manufacturing cost of the display device.

In the display device and the repairing method thereof in accordance with embodiments of the present disclosure, although a dark spot defect occurs in a sub-pixel, the sub-pixel can be readily repaired, thereby improving the reliability of the display device.

In accordance with embodiments of the present disclosure, without replacing a defective light emitting element connected in the reverse direction between electrode, portions of the electrodes are removed using a laser, and a conductive pattern under the electrodes and the electrodes are electrically connected to each other by performing a laser bonding process, such that the defective light emitting element can be connected in the forward direction between the electrodes. Accordingly, the defective light emitting element is used as an effective light source, such that light emitting elements can be prevented or substantially prevented from being unnecessarily wasted, thereby reducing the manufacturing cost of the display device.

In accordance with embodiments of the present disclosure, a sub-electrode electrically connected to each end portion of a light emitting element while being in contact with the end portion of the light emitting element is provided in plural, thereby providing a plurality of current paths between the light emitting element and the sub-pixel, such that the reliability of the display device is improved.

Some example embodiments have been disclosed herein, and although specific terms are employed, they are used and are to be interpreted in a generic and descriptive sense and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it is to be understood by those of skill in the art that various changes in form and details may be made without departing from the spirit and scope of the present disclosure as set forth in the following claims.

What is claimed is:

1. A display device comprising:
a substrate;
a first conductive pattern and a second conductive pattern on the substrate, the first conductive pattern and the second conductive pattern being spaced apart from each other;
a first electrode, a second electrode, a third electrode, and a fourth electrode on the first and second conductive patterns, the first electrode, the second electrode, the third electrode, and the fourth electrode being spaced apart from each other; and
a light emitting element on the first and second electrodes,
wherein the first electrode is electrically connected to the first conductive pattern, and the second electrode is electrically connected to the second conductive pattern, and
wherein the first conductive pattern is electrically disconnected from the second electrode and the second conductive pattern, and
the second conductive pattern is electrically disconnected from the first electrode and the first conductive pattern.

2. The display device of claim 1, wherein the first conductive pattern overlaps with the first electrode, the second electrode, and the fourth electrode, and
the second conductive pattern overlaps with the first electrode, the second electrode, and the third electrode.

3. The display device of claim 2, wherein the first electrode and the third electrode are integrally formed to be electrically connected to each other, and
the second electrode and the fourth electrode are integrally formed to be electrically connected to each other.

4. The display device of claim 3, further comprising:
a transistor on the substrate, the transistor being electrically connected to the first and third electrodes;
a common line on the substrate, the common line being integrally formed with the second and fourth electrodes to be electrically connected to the second and fourth electrodes; and
a power line on the substrate, the power line being electrically connected to the common line, the power line being supplied with a low-potential voltage.

5. The display device of claim 4, wherein the first electrode comprises two or more first sub-electrodes spaced apart from each other, and
the second electrode comprises two or more second sub-electrodes spaced apart from each other, and
wherein the first sub-electrodes are electrically connected to each other, and the second sub-electrodes are electrically connected to each other.

6. The display device of claim 5, further comprising:
a first connection line on the first and second conductive patterns, the first connection line being integrally formed with the first sub-electrodes to be electrically connected to the first sub-electrodes; and
a second connection line on the first and second conductive patterns, the second connection line being integrally formed with the second sub-electrodes to be electrically connected to the second sub-electrodes.

7. The display device of claim 6, wherein the first conductive pattern is electrically connected to at least one of the first sub-electrodes, and
the second conductive pattern is electrically connected to at least one of the second sub-electrodes.

8. The display device of claim 7, further comprising an insulating layer between the first and second conductive patterns and the first to fourth electrodes, the insulating layer comprising a first contact portion exposing an end of the first conductive pattern and a second contact portion exposing an end of the second conductive pattern,
wherein at least one of the first sub-electrodes is electrically connected to the first conductive pattern through the first contact portion, and
at least one of the second sub-electrodes is electrically connected to the second conductive pattern through the second contact portion.

9. The display device of claim 4, wherein the light emitting element has horizontal type structure including a first end portion and a second end portion which are located on a same plane, and
wherein the light emitting element comprises:
a semiconductor structure including a first semiconductor layer, an active layer on the first semiconductor layer, and a second semiconductor layer on the active layer;
a first contact electrode on the semiconductor structure, the first contact electrode being electrically connected to the first semiconductor layer, the first contact electrode being located at the second end portion; and
a second contact electrode on the semiconductor structure to be spaced apart from the first contact electrode, the second contact electrode being electrically connected to the second semiconductor layer, the second contact electrode being located at the first end portion.

10. The display device of claim 9, wherein the first semiconductor layer comprises an n-type semiconductor layer doped with an n-type dopant, and the second semiconductor layer comprises a p-type semiconductor layer doped with a p-type dopant.

11. The display device of claim 10, wherein the first end portion of the light emitting element is electrically connected to the first sub-electrodes, and
the second end portion of the light emitting element is electrically connected to the second sub-electrodes.

12. The display device of claim 11, wherein the first electrode is an anode electrode, and the second electrode is a cathode electrode.

13. A display device comprising:
a substrate;
a first conductive pattern and a second conductive pattern on the substrate, the first conductive pattern and the second conductive pattern being spaced apart from each other;
an insulating layer on the first and second conductive patterns, the insulating layer comprising a first contact portion exposing a first end of the first conductive pattern, a second contact portion exposing a first end of the second conductive pattern, a third contact portion exposing a second end of the first conductive pattern, and a fourth contact portion exposing a second end of the second conductive pattern;
a first electrode on the insulating layer, the first electrode comprising two or more first sub-electrodes;
a second electrode on the insulating layer, the second electrode comprising two or more second sub-electrodes;
a third electrode spaced apart from the first and second electrodes;
a fourth electrode spaced apart from the first to third electrodes; and
a light emitting element on the first electrode and the second electrode,
wherein at least one of the first sub-electrodes is electrically connected to the first end of the first conductive pattern through the first contact portion, and the fourth electrode is electrically connected to the second end of the first conductive pattern through the third contact portion, and
wherein at least one of the second sub-electrodes is electrically connected to the first end of the second conductive pattern through the second contact portion, and the third electrode is electrically connected to the second end of the second conductive pattern through the fourth contact portion.

14. The display device of claim 13, wherein the light emitting element comprises a first end portion and a second end portion, which are located on a same plane, wherein the first end portion is electrically connected to the second sub-electrodes, and the second end portion is electrically connected to the first sub-electrodes, and
wherein a p-type semiconductor layer is located at the first end portion, and an n-type semiconductor layer is located at the second end portion.

15. The display device of claim 14, further comprising:
a transistor on the substrate, the transistor being electrically connected to the third electrode;
a common line on the substrate, the common line being integrally formed with the fourth electrode to be electrically connected to the fourth electrode; and
a power line on the substrate, the power line being electrically connected to the common line, the power line being supplied with a low-potential voltage,
wherein the first sub-electrodes are electrically connected to the fourth electrode through the first conductive pattern, and
the second sub-electrodes are electrically connected to the third electrode through the second conductive pattern.

16. The display device of claim 15, wherein the first sub-electrodes are electrically disconnected from the third electrode, and the second sub-electrodes are electrically disconnected from the fourth electrode.

17. The display device of claim 15, wherein the first sub-electrodes correspond to a cathode electrode, and the second sub-electrodes correspond to an anode electrode.

18. A method of repairing a display device,
wherein the display device comprises:
a substrate;
a first conductive pattern and a second conductive pattern on the substrate, the first conductive pattern and the second conductive pattern being spaced apart from each other;
a first electrode on the first and second conductive patterns, the first electrode including two or more first sub-electrodes, the first electrode being electrically connected to a first end of the first conductive pattern;
a second electrode on the first and second conductive patterns, the second electrode including two or more second sub-electrodes, the second electrode being electrically connected to a first end of the second conductive pattern;
a third electrode on the second conductive pattern, the third electrode being electrically connected to the first sub-electrodes, the third electrode overlapping with a second end of the second conductive pattern;
a fourth electrode on the first conductive pattern, the fourth electrode being electrically connected to the second sub-electrodes, the fourth electrode overlapping with a second end of the first conductive pattern; and
a light emitting element electrically connected to the first sub-electrodes and the second sub-electrodes,
the method comprising:
electrically disconnecting the first sub-electrodes and the third electrode from each other and electrically disconnecting the second sub-electrodes and the fourth electrode, using a laser, in a case in which the light emitting element is a defective light emitting element; and
electrically connecting the second end of the first conductive pattern and the fourth electrode to each other by irradiating a laser onto a top of an overlapping area of the first conductive pattern and the fourth electrode and then removing a portion of an insulating layer between the first conductive pattern and the fourth electrode, and electrically connecting the second end of the second conductive pattern and the third electrode to each other by irradiating a laser onto a top of an overlapping area of the second conductive pattern and the third electrode and then removing another portion of the insulating layer between the second conductive pattern and the third electrode.

19. The method of claim 18, wherein the defective light emitting element comprises a first end portion and a second end portion, which are located on a same plane, wherein the first end portion is electrically connected to the second sub-electrodes and the fourth electrode, and the second end portion is electrically connected to the first sub-electrodes and the third electrode, and
wherein a p-type semiconductor layer is located at the first end portion, and an n-type semiconductor layer is located at the second end portion.

20. The method of claim 18, wherein the display device further comprises:
a transistor on the substrate, the transistor being electrically connected to the third electrode;
a common line on the substrate, the common line being integrally formed with the fourth electrode to be electrically connected to the fourth electrode; and
a power line on the substrate, the power line being electrically connected to the common line, the power line being supplied with a low-potential voltage,
wherein the first sub-electrodes are electrically connected to the fourth electrode through the first conductive pattern, and
the second sub-electrodes are electrically connected to the third electrode through the second conductive pattern.
